(19) United States
(12) Patent Application Publication
(10) Pub. No.: US 2025/0008781 A1
(43) Pub. Date: Jan. 2, 2025

(54) Display Apparatus, Display Module, and Electronic Device

(71) Applicant: Semiconductor Energy Laboratory Co., Ltd., Kanagawa-ken (JP)

(72) Inventors: Shinya SASAGAWA, Chigasaki, Kanagawa (JP); Ryota HODO, Atsugi, Kanagawa (JP); Kentaro SUGAYA, Isehara, Kanagawa (JP); Yuichi YANAGISAWA, Atsugi, Kanagawa (JP)

(73) Assignee: Semiconductor Energy Laboratory Co., Ltd., Kanagawa-ken (JP)

(21) Appl. No.: 18/707,755

(22) PCT Filed: Oct. 31, 2022
(86) PCT No.: PCT/IB2022/060447

§ 371 Date: May 6, 2024

(30) Foreign Application Priority Data
Nov. 11, 2021 (JP) 2021-183777

(51) Int. Cl. H10K 59/122

(52) U.S. Cl. CPC H10K 59/122

(57) ABSTRACT

A high-resolution display apparatus is provided. The display apparatus includes a first light-emitting device, a second light-emitting device, a first sidewall insulating layer, a second sidewall insulating layer, an insulating layer, a first coloring layer, and a second coloring layer. The first light-emitting device includes a first pixel electrode, a first EL layer, and a common electrode. The second light-emitting device includes a second pixel electrode, a second EL layer, and the common electrode. The first EL layer and the second EL layer emit white light. The first sidewall insulating layer is in contact with the side surface of the first pixel electrode. The second sidewall insulating layer is in contact with the side surface of the second pixel electrode. The insulating layer covers the side surface and part of the top surface of the first EL layer and the side surface and part of the top surface of the second EL layer. The first coloring layer overlaps with the first light-emitting device. The second coloring layer overlaps with the second light-emitting device. The first coloring layer and the second coloring layer have functions of transmitting light of different colors.

### TECHNICAL FIELD

One embodiment of the present invention relates to a display apparatus, a display module, and an electronic device. One embodiment of the present invention relates to a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, a lighting device, an input device (e.g., a touch sensor), an input/output device (e.g., a touch panel), a display module including any of these apparatuses and devices, an electronic device including the display module, a method for driving any of them, and a method for manufacturing any of them.

### BACKGROUND ART

Recent display apparatuses have been expected to be applied to a variety of uses. Usage examples of large-sized display apparatuses include a television device for home use (also referred to as TV or television receiver), digital signage, and a PID (Public Information Display). In addition, a smartphone, a tablet terminal, or the like including a touch panel is being developed as a portable information terminal.

Furthermore, display apparatuses have been required to have higher resolution. As devices requiring high-resolution display apparatuses, for example, devices for virtual reality (VR), augmented reality (AR), substitutional reality (SR), or mixed reality (MR) have been actively developed.

Light-emitting apparatuses including light-emitting devices (also referred to as light-emitting elements) have been developed as display apparatuses, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display apparatuses.

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a high-resolution display apparatus. An object of one embodiment of the present invention is to provide a high-definition display apparatus. An object of one embodiment of the present invention is to provide a highly reliable display apparatus.

An object of one embodiment of the present invention is to provide a method for manufacturing a high-resolution display apparatus. An object of one embodiment of the present invention is to provide a method for manufacturing a high-definition display apparatus. An object of one embodiment of the present invention is to provide a method for manufacturing a highly reliable display apparatus. An object of one embodiment of the present invention is to provide a method for manufacturing a display apparatus with high yield.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a display apparatus that includes a first light-emitting device, a second light-emitting device, a first sidewall insulating layer, a second sidewall insulating layer, a first insulating layer, a first coloring layer, and a second coloring layer. The first light-emitting device includes a first pixel electrode, a first EL layer over the first pixel electrode, and a common electrode over the first EL layer. The second light-emitting device includes a second pixel electrode, a second EL layer over the second pixel electrode, and the common electrode over the second EL layer. The first EL layer and the second EL layer each include a first light-emitting material emitting blue light and a second light-emitting material emitting light having a longer wavelength than blue light. The first sidewall insulating layer is in contact with a side surface of the first pixel electrode. The second sidewall insulating layer is in contact with a side surface of the second pixel electrode. The first insulating layer covers a side surface and part of a top surface of the first EL layer and a side surface and part of a top surface of the second EL layer. The first coloring layer overlaps with the first light-emitting device. The second coloring layer overlaps with the second light-emitting device. The first coloring layer and the second coloring layer have functions of transmitting light of different colors.

In the above, a material layer isolated from the first EL layer and the second EL layer is preferably provided between the first light-emitting device and the second light-emitting device. The material layer preferably contains the first light-emitting material and the second light-emitting material.

In the above, each of the first sidewall insulating layer and the second sidewall insulating layer preferably includes an inorganic insulating material.

In the above, the first insulating layer preferably has a tapered end portion.

In the above, the first insulating layer preferably contains an organic insulating material.

In the above, a second insulating layer covering the side surface and the part of the top surface of the first EL layer and the side surface and the part of the top surface of the second EL layer is preferably provided. The first insulating layer is preferably provided over the second insulating layer.

In the above, the second insulating layer preferably has a tapered end portion.

In the above, the second insulating layer preferably contains an inorganic insulating material.

One embodiment of the present invention is a display module that includes the above-described display apparatus and at least one of a connector and an integrated circuit.

One embodiment of the present invention is an electronic device that includes the above-described display module and at least one of a housing, a battery, a camera, a speaker, and a microphone.

### Effect of the Invention

According to one embodiment of the present invention, a high-resolution display apparatus can be provided. According to one embodiment of the present invention, a high-definition display apparatus can be provided. According to one embodiment of the present invention, a highly reliable display apparatus can be provided.

According to one embodiment of the present invention, a method for manufacturing a high-resolution display apparatus can be provided. According to one embodiment of the present invention, a method for manufacturing a high-definition display apparatus can be provided. According to one embodiment of the present invention, a method for manufacturing a highly reliable display apparatus can be provided. According to one embodiment of the present invention, a method for manufacturing a display apparatus with high yield can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2 is a cross-sectional view illustrating an example of a display apparatus.

FIG. 3A to FIG. 3D are cross-sectional views illustrating examples of a display apparatus.

FIG. 4A and FIG. 4B are cross-sectional views illustrating an example of a display apparatus.

FIG. 5A and FIG. 5B are cross-sectional views illustrating an example of a display apparatus.

FIG. 6A and FIG. 6B are cross-sectional views illustrating examples of a display apparatus.

FIG. 7A and FIG. 7B are cross-sectional views illustrating examples of a display apparatus.

FIG. 8A and FIG. 8B are cross-sectional views illustrating examples of a display apparatus.

FIG. 9A to FIG. 9C are cross-sectional views illustrating examples of a display apparatus.

FIG. 10 is a cross-sectional view illustrating an example of a display apparatus.

FIG. 11A and FIG. 11B are cross-sectional views illustrating examples of a display apparatus.

FIG. 12A and FIG. 12B are cross-sectional views illustrating examples of a display apparatus.

FIG. 13A and FIG. 13B are cross-sectional views illustrating examples of a display apparatus.

FIG. 14A to FIG. 14E are cross-sectional views illustrating an example of the method for manufacturing a display apparatus.

FIG. 15A to FIG. 15D are cross-sectional views illustrating an example of the method for manufacturing a display apparatus.

FIG. 16A to FIG. 16F are cross-sectional views illustrating an example of a method for manufacturing a display apparatus.

FIG. 17A to FIG. 17G are diagrams illustrating examples of a pixel.

FIG. 18A to FIG. 18I are diagrams illustrating examples of a pixel.

FIG. 19A and FIG. 19B are perspective views illustrating an example of a display apparatus.

FIG. 20 is a cross-sectional view illustrating an example of a display apparatus.

FIG. 21 is a cross-sectional view illustrating an example of a display apparatus.

FIG. 22 is a cross-sectional view illustrating an example of a display apparatus.

FIG. 23 is a cross-sectional view illustrating an example of a display apparatus.

FIG. 24 is a cross-sectional view illustrating an example of a display apparatus.

FIG. 25 is a cross-sectional view illustrating an example of a display apparatus.

FIG. 26 is a perspective view illustrating an example of a display apparatus.

FIG. 27A is a cross-sectional view illustrating an example of a display apparatus.

FIG. 27B and

FIG. 27C are cross-sectional views illustrating examples of a transistor.

FIG. 28A to FIG. 28D are cross-sectional views illustrating examples of a display apparatus.

FIG. 29A to FIG. 29F are diagrams illustrating structure examples of a light-emitting device.

FIG. 30A to FIG. 30C are diagrams illustrating structure examples of a light-emitting device.

FIG. 31A to FIG. 31D are diagrams illustrating examples of an electronic device.

FIG. 32A to FIG. 32F are diagrams illustrating examples of an electronic device.

FIG. 33A to FIG. 33G are diagrams illustrating examples of an electronic device.

### MODE FOR CARRYING OUT THE INVENTION

Hereinafter, embodiments will be described in detail with reference to the drawings. Note that the present invention is not limited to the following description, and it is easily understood by those skilled in the art that the mode and details can be variously changed without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

The term “film” and the term “layer” can be interchanged with each other depending on the case or circumstances. For example, the term “conductive layer” can be replaced with the term “conductive film”. As another example, the term “insulating film” can be replaced with the term “insulating layer”.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM is sometimes referred to as a device having an MML (metal maskless) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting device includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

Note that in this specification and the like, disconnection refers to a phenomenon in which a layer, a film, or an electrode is split because of the shape of the formation surface (e.g., a step).

In this specification and the like, a tapered shape refers to a shape in which at least part of the side surface of a structure is inclined to a substrate surface or a formation surface. For example, a tapered shape refers to a shape including a region where the angle between the inclined side surface and the substrate surface or the formation surface (also referred to as a taper angle) is less than 90°. Note that the side surface of the structure, the formation surface, and the substrate surface are not necessarily completely flat and may be substantially flat with a slight curvature or substantially flat with slight unevenness.

### Embodiment 1

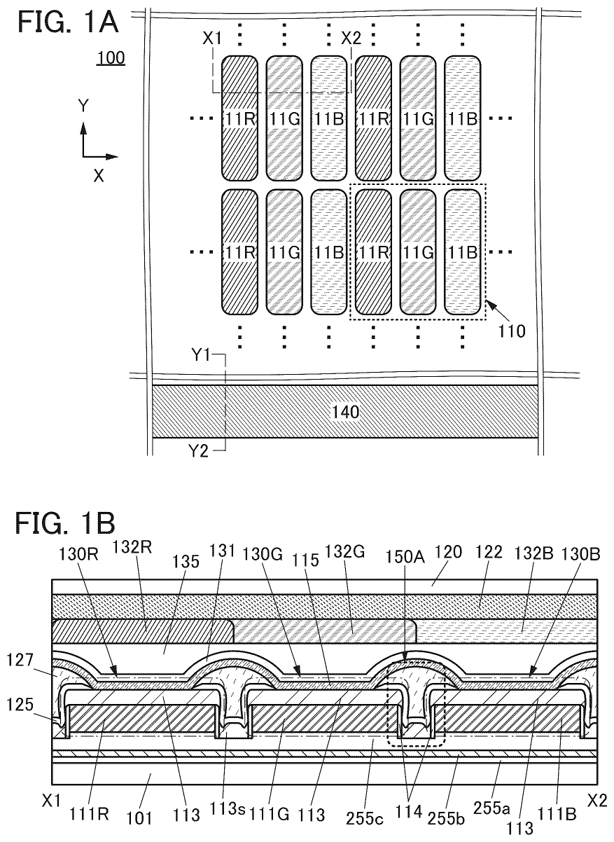

In this embodiment, a display apparatus of one embodiment of the present invention will be described with reference to FIG. 1 to FIG. 13.

The display apparatus of one embodiment of the present invention includes a plurality of subpixels. The subpixels include light-emitting devices containing the same light-emitting material and coloring layers overlapping with the light-emitting devices. Coloring layers that transmit visible light of different colors are provided for the subpixels, whereby full-color display can be performed.

In the case where light-emitting devices including the same light-emitting material are used, layers included in the light-emitting devices other than a pixel electrode (e.g., a light-emitting layer) can be used in common between a plurality of subpixels. Therefore, the plurality of subpixels can share one continuous film. However, some of the layers included in the light-emitting devices have relatively high conductivity. When the plurality of subpixels share a continuous film with high conductivity, leakage current might be generated between the subpixels. Particularly when an increase in the resolution or the aperture ratio of a display apparatus reduces the distance between subpixels, the leakage current might become too large to ignore and cause a decrease in display quality of the display apparatus, for example.

In view of the above, in the display apparatus of one embodiment of the present invention, an EL layer shared by a plurality of light-emitting devices has a locally thinned portion or a plurality of light-emitting devices each include an island-shaped EL layer. The EL layer has a portion with a small thickness (also referred to as a thin portion) or EL layers are separately formed for the light-emitting devices, whereby generation of crosstalk between adjacent subpixels can be inhibited. This enables the display apparatus to have high color reproducibility and high contrast, so that the display apparatus can have both high resolution and high display quality. Note that in the display apparatus of one embodiment of the present invention, island-shaped EL layers may be formed in some subpixels; in that case, an EL layer may be formed as a continuous layer in the other subpixels. In that case, the continuous layer preferably has a locally thinned portion.

For example, an island-shaped EL layer can be formed by a vacuum evaporation method using a metal mask. However, this method causes a deviation from the designed shape and position of an island-shaped EL layer due to various influences such as low accuracy of the metal mask, positional deviation between the metal mask and a substrate, a warp of the metal mask, and vapor-scattering-induced expansion of the outline of a film to be deposited; accordingly, it is difficult to achieve high resolution and a high aperture ratio of the display apparatus. In addition, the outline of the layer may blur during vapor deposition, whereby the thickness of an end portion may be small. That is, the thickness of the island-shaped EL layer formed using a metal mask may vary from area to area. In the case where a display apparatus with a large size, high definition, or high resolution is manufactured, the manufacturing yield might be reduced because of low dimensional accuracy of the metal mask and a change in shape due to heat or the like.

In view of the above, in manufacture of the display apparatus of one embodiment of the present invention, an island-shaped EL layer is formed without using a shadow mask (e.g., a metal mask).

For example, as the difference between the level of the top surface of an insulating layer exposed between adjacent pixel electrodes and the level of the top surface of the pixel electrode (also referred to as a step between adjacent pixel electrodes) is larger, it becomes easier to form a locally thinned portion in an EL layer and to split the EL layer to form island-shaped EL layers for light-emitting devices. By utilizing the step between adjacent pixel electrodes, the EL layer can be locally thinned or split in a self-aligned manner in deposition of the EL layer. In other words, generation of crosstalk can be inhibited without increasing the number of steps, so that a display apparatus with high color reproducibility and high contrast can be achieved.

Note that when the EL layer has a portion with a small thickness or the EL layers are separately formed for the light-emitting devices, the light-emitting device might be short-circuited due to contact between an exposed portion of the pixel electrode and a common electrode, for example.

For that reason, in a method for manufacturing a display apparatus of one embodiment of the present invention, a sidewall insulating layer (also referred to as a sidewall, a sidewall protective layer, an insulating layer, or the like) is provided in contact with the side surface of the pixel electrode. This can inhibit contact between the pixel electrode and the common electrode, thereby preventing a short circuit of the light-emitting device and improving the reliability of the light-emitting device.

In the case where a step between adjacent pixel electrodes is large, the common electrode provided over the EL layer might be disconnected due to the step.

In view of the above, in the method for manufacturing a display apparatus of one embodiment of the present invention, an insulating layer is provided to cover at least the side surface and part of the top surface of an island-shaped EL layer. Then, a common electrode is provided to cover the insulating layer and the EL layer. Thus, disconnection of the common electrode due to a step between adjacent pixel electrodes can be inhibited.

Note that an end portion of the insulating layer preferably has a tapered shape with a taper angle of less than 90° in a cross-sectional view. This can prevent disconnection of the common electrode provided over the insulating layer and inhibit a connection defect of the common electrode. Moreover, an increase in electric resistance of the common electrode, which is caused by local thinning of the common electrode due to a step of the end portion of the insulating layer, can be inhibited.

As described above, in the method for manufacturing a display apparatus of one embodiment of the present invention, the island-shaped EL layers are formed not by using a fine metal mask but by utilizing the step between adjacent pixel electrodes. Accordingly, a high-resolution display apparatus or a display apparatus with a high aperture ratio, which has been difficult to achieve, can be achieved.

A formation method using a fine metal mask, for example, does not easily reduce the distance between adjacent light-emitting regions (also referred to as the shortest distance) to less than 10 μm; by contrast, the method for manufacturing a display apparatus of one embodiment of the present invention can shorten the distance between adjacent light-emitting regions, the distance between adjacent EL layers, the distance between adjacent sidewall insulating layers, or the distance between adjacent pixel electrodes to less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm, for example, in a process over a glass substrate. Using a light exposure apparatus for LSI can further shorten the distance between adjacent light-emitting regions, the distance between adjacent EL layers, the distance between adjacent sidewall insulating layers, or the distance between adjacent pixel electrodes to 500 nm or less, 200 nm or less, 100 nm or less, or even 50 nm or less, for example, in a process over a Si wafer. Accordingly, the area of a non-light-emitting region that may exist between two light-emitting devices can be significantly reduced, and the aperture ratio can be close to 100%. For example, the aperture ratio of the display apparatus of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display apparatus can improve the reliability of the display apparatus. Specifically, the density of current flowing through the light-emitting device can be reduced with an increasing aperture ratio, and accordingly the lifetime of the display apparatus can be increased.

The display apparatus of one embodiment of the present invention can have a resolution higher than or equal to 1,000 ppi, preferably higher than or equal to 2,000 ppi, further preferably higher than or equal to 3,000 ppi, still further preferably higher than or equal to 5,000 ppi, yet still further preferably higher than or equal to 6,000 ppi, and lower than or equal to 20,000 ppi or lower than or equal to 30,000 ppi.

In this embodiment, cross-sectional structures of the display apparatus of one embodiment of the present invention are mainly described, and a method for manufacturing the display apparatus of one embodiment of the present invention will be described in detail in Embodiment 2.

FIG. 1A is a top view of a display apparatus 100. The display apparatus 100 includes a display portion in which a plurality of pixels 110 are arranged and a connection portion 140 outside the display portion. A plurality of subpixels are arranged in a matrix in the display portion. FIG. 1A illustrates subpixels in two rows and six columns, which form pixels 110 in two rows and two columns. The connection portion 140 can also be referred to as a cathode contact portion.

The top surface shape of the subpixel illustrated in FIG. 1A corresponds to the top surface shape of a light-emitting region.

Examples of the top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in FIG. 1A, and the components may be placed outside the range of the subpixels. In other words, some or all of the transistors (not illustrated) included in a subpixel 11R illustrated in FIG. 1A may be positioned outside the range of the subpixel 11R. The transistors included in the subpixel 11R may be positioned within the range of the subpixel 11R illustrated in FIG. 1A, may be positioned within the range of a subpixel 11G, may be positioned within the range of a subpixel 11B, or may be provided across two or more of the ranges of the subpixels.

Although the subpixel 11R, the subpixel 11G, and the subpixel 11B have the same or substantially the same aperture ratio (also referred to as the same size or the same size of a light-emitting region) in FIG. 1A, one embodiment of the present invention is not limited thereto. The aperture ratios of the subpixel 11R, the subpixel 11G, and the subpixel 11B can each be determined as appropriate. The subpixel 11R, the subpixel 11G, and the subpixel 11B may have different aperture ratios, or two or more of the subpixel 11R, the subpixel 11G, and the subpixel 11B may have the same or substantially the same aperture ratio.

The pixel 110 illustrated in FIG. 1A employs stripe arrangement. The pixel 110 illustrated in FIG. 1A is composed of three subpixels: the subpixel 11R, the subpixel 11G, and the subpixel 11B. The subpixel 11R, the subpixel 11G, and the subpixel 11B emit light of different colors. Examples of the subpixel 11R, the subpixel 11G, and the subpixel 11B include subpixels of three colors of red (R), green (G), and blue (B) and subpixels of three colors of yellow (Y), cyan (C), and magenta (M). The number of types of subpixels is not limited to three and may be four or more. Examples of the four subpixels include subpixels of four colors of R, G, B, and white (W), subpixels of four colors of R, G, B, and Y, and four subpixels of R, G, B, and infrared light (IR).

In this specification and the like, the row direction is referred to as X direction and the column direction is referred to as Y direction in some cases. The X direction and the Y direction intersect with each other and are, for example, orthogonal to each other (see FIG. 1A). FIG. 1A illustrates an example in which subpixels of different colors are arranged in the X direction and subpixels of the same color are arranged in the Y direction.

Although the top view of FIG. 1A illustrates an example in which the connection portion 140 is positioned on the lower side of the display portion, there is no particular limitation on the position of the connection portion 140. The connection portion 140 is provided in at least one of the upper side, the right side, the left side, and the lower side of the display portion in the top view, or may be provided so as to surround the four sides of the display portion. The top surface shape of the connection portion 140 can be a belt-like shape, an L shape, a U shape, a frame-like shape, or the like. The number of the connection portions 140 can be one or more.

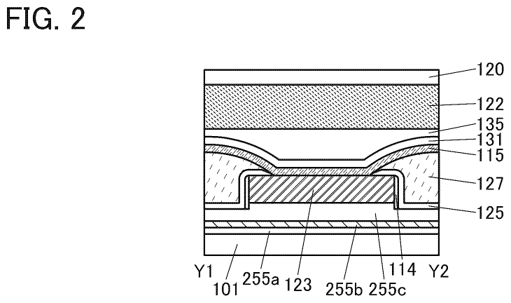

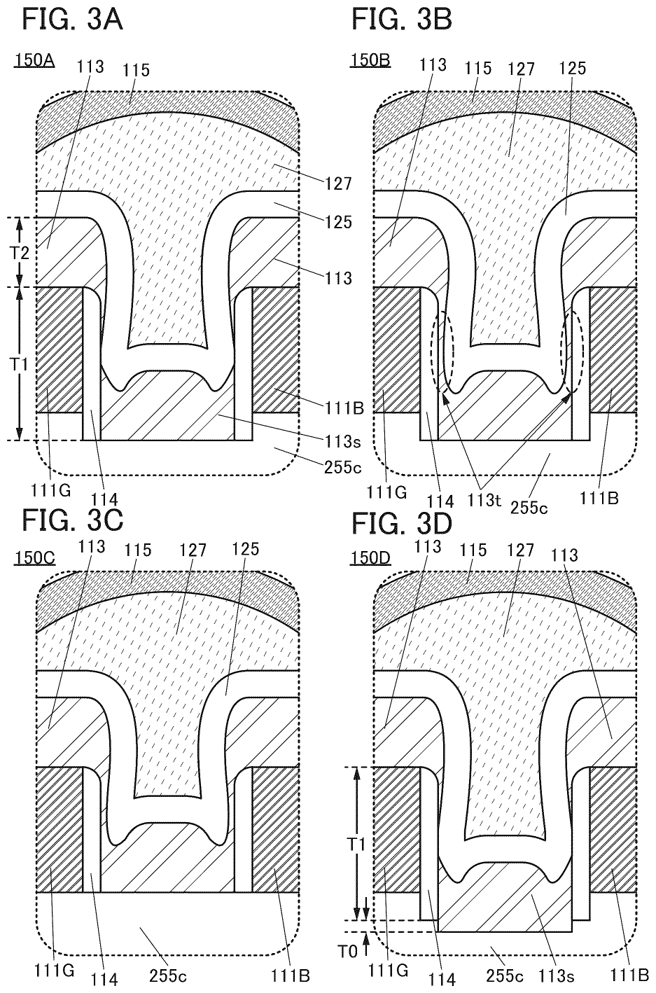

FIG. 1B is a cross-sectional view along the dashed dotted line X1-X2 in FIG. 1A. FIG. 2 is a cross-sectional view along the dashed dotted line Y1-Y2 in FIG. 1A. FIG. 3A is an enlarged view of a region 150A illustrated in FIG. 1B. FIG. 3B to FIG. 3D illustrate a region 150B to a region 150D, respectively, that are variation examples of the region 150A.

The subpixel 11R includes a light-emitting device 130R and a coloring layer 132R transmitting red light. Thus, light emitted from the light-emitting device 130R is extracted as red light to the outside of the display apparatus through the coloring layer 132R.

The subpixel 11G includes a light-emitting device 130G and a coloring layer 132G transmitting green light. Thus, light emitted from the light-emitting device 130G is extracted as green light to the outside of the display apparatus through the coloring layer 132G.

The subpixel 11B includes a light-emitting device 130B and a coloring layer 132B transmitting blue light. Thus, light emitted from the light-emitting device 130B is extracted as blue light to the outside of the display apparatus through the coloring layer 132B.

An example of blue light is light having a peak wavelength in the emission spectrum of greater than or equal to 400 nm and less than 480 nm. An example of green light is light having a peak wavelength in the emission spectrum of greater than or equal to 480 nm and less than 580 nm. An example of red light is light having a peak wavelength in the emission spectrum of greater than or equal to 580 nm and less than or equal to 700 nm.

The coloring layer is a colored layer that selectively transmits light in a specific wavelength range and absorbs light in the other wavelength ranges. As the coloring layer 132R, a color filter transmitting light in the red wavelength range can be used, for example. As the coloring layer 132G, a color filter transmitting light in the green wavelength range can be used, for example. As the coloring layer 132B, a color filter transmitting light in the blue wavelength range can be used, for example. Examples of materials that can be used for the coloring layer include a metal material, a resin material, and a resin material containing a pigment or dye.

As illustrated in FIG. 1B, in the display apparatus 100, insulating layers (an insulating layer 255a, an insulating layer 255b, and an insulating layer 255c) are provided over a layer 101 including transistors (not illustrated), a light-emitting device 130R, a light-emitting device 130G, and a light-emitting device 130B are provided over the insulating layers, and a protective layer 131 and an insulating layer 135 are provided to cover these light-emitting devices. The coloring layer 132R, the coloring layer 132G, and the coloring layer 132B are provided over the insulating layer 135, and a substrate 120 is bonded onto the coloring layer 132R, the coloring layer 132G, and the coloring layer 132B with a resin layer 122. The coloring layer 132R is provided in a position overlapping the light-emitting device 130R. The coloring layer 132G is provided in a position overlapping the light-emitting device 130G. The coloring layer 132B is provided in a position overlapping with the light-emitting device 130B. In a region between adjacent light-emitting devices, an insulating layer 125 and an insulating layer 127 over the insulating layer 125 are provided.

Although FIG. 1B illustrates a plurality of cross sections of the insulating layer 125 and the insulating layer 127, the insulating layer 125 and the insulating layer 127 are each one continuous layer when the display apparatus 100 is seen from above. In other words, the display apparatus 100 can have a structure including one insulating layer 125 and one insulating layer 127, for example. Note that the display apparatus 100 may include a plurality of insulating layers 125 that are separated from each other and a plurality of insulating layers 127 that are separated from each other.

The display apparatus of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces. In this embodiment, a top-emission display apparatus is described as an example.

The layer 101 can have a stacked-layer structure in which a plurality of transistors (not illustrated) are provided over a substrate and an insulating layer is provided to cover these transistors, for example. The insulating layer over the transistors may have a single-layer structure or a stacked-layer structure. In FIG. 1B, an insulating layer 255a, an insulating layer 255b over the insulating layer 255a, and an insulating layer 255c over the insulating layer 255b are illustrated as the insulating layers over the transistors. Note that the insulating layers (the insulating layer 255a to the insulating layer 255c) over the transistors can be regarded as part of the layer 101.

As described later, the insulating layer 255c preferably has a depressed portion between two adjacent light-emitting devices. In that case, EL layers are formed in the state where a large step is provided between adjacent pixel electrodes, so that the EL layers can be easily formed separately for light-emitting devices. In the example illustrated in FIG. 1B, the insulating layer 255c has a depressed portion. The insulating layer 255c may have an opening between two adjacent light-emitting devices; in that case, the insulating layer 255b may have a depressed portion.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and that a silicon nitride film be used as the insulating layer 255b. The insulating layer 255b preferably has a function of an etching protective film.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content.

Structure examples of the layer 101 will be described later in Embodiment 4.

As the light-emitting device, for example, an OLED (Organic Light Emitting Diode) and a QLED (Quantum-dot Light-Emitting Diode) are preferably used. Examples of a light-emitting substance contained in the light-emitting device include a substance exhibiting fluorescence (a fluorescent material), a substance exhibiting phosphorescence (a phosphorescent material), a substance exhibiting thermally activated delayed fluorescence (a thermally activated delayed fluorescence (TADF) material), and an inorganic compound (e.g., a quantum dot material). An LED (Light Emitting Diode) such as a micro-LED can also be used as the light-emitting device.

The light-emitting device can emit infrared, red, green, blue, cyan, magenta, yellow, or white light, for example. When the light-emitting device has a microcavity structure, the color purity can be increased.

Of a pair of electrodes included in the light-emitting device, an electrode through which light is extracted is preferably formed using a conductive film that transmits visible light and the other electrode through which light is not extracted is preferably formed using a conductive film that reflects visible light.

One of the pair of electrodes included in the light-emitting device functions as an anode, and the other electrode functions as a cathode. The case where the pixel electrode functions as an anode and the common electrode functions as a cathode is described below as an example in some cases.

The light-emitting device 130R includes a pixel electrode 111R over the insulating layer 255c, an island-shaped EL layer 113 over the pixel electrode 111R, and a common electrode 115 over the EL layer 113.

The light-emitting device 130G includes a pixel electrode 111G over the insulating layer 255c, the island-shaped EL layer 113 over the pixel electrode 111G, and the common electrode 115 over the EL layer 113.

The light-emitting device 130B includes a pixel electrode 111B over the insulating layer 255c, the island-shaped EL layer 113 over the pixel electrode 111B, and the common electrode 115 over the EL layer 113.

The light-emitting device 130R, the light-emitting device 130G, and the light-emitting device 130B each independently include the island-shaped EL layer 113. These EL layers 113 are formed in the same step and have the same structure. Therefore, these EL layers 113 can be regarded as containing the same light-emitting material.

The EL layer 113 can be configured to emit white light. For example, the EL layer 113 contains a first light-emitting material that emits blue light and a second light-emitting material that emits light having a longer wavelength than blue light.

Note that in the case where the light-emitting device including the EL layer configured to emit white light has a microcavity structure, light of a specific wavelength such as red, green, or blue is sometimes intensified and then emitted.

For example, the EL layer 113 is configured to emit white light and has a microcavity structure, whereby red light emission can be obtained from the light-emitting device 130R, green light emission can be obtained from the light-emitting device 130G, and blue light emission can be obtained from the light-emitting device 130B.

The light-emitting device of this embodiment may have either a single structure (a structure including only one light-emitting unit) or a tandem structure (a structure including a plurality of light-emitting units). The light-emitting unit includes at least one light-emitting layer.

The EL layer 113 includes at least a light-emitting layer. For example, the EL layer 113 can have a structure including a light-emitting layer that emits blue light and a light-emitting layer that emits light having a longer wavelength than blue light.

In the case where the light-emitting device has a tandem structure, the EL layer 113 can have a structure including a light-emitting unit that emits blue light and a light-emitting unit that emits light having a longer wavelength than blue light, for example. A charge-generation layer (also referred to an intermediate layer) is preferably provided between the light-emitting units. The tandem structure enables a light-emitting device capable of high-luminance light emission to be obtained.

The EL layer 113 may include one or more of a hole-injection layer, a hole-transport layer, a hole-blocking layer, a charge-generation layer, an electron-blocking layer, an electron-transport layer, and an electron-injection layer.

For example, the EL layer 113 may include a hole-injection layer, a hole-transport layer, a light-emitting layer, an electron-transport layer, and an electron-injection layer in this order from the anode side. In addition, an electron-blocking layer may be provided between the hole-transport layer and the light-emitting layer. In addition, a hole-blocking layer may be provided between the electron-transport layer and the light-emitting layer.

The EL layer 113 may include a first light-emitting unit, a charge-generation layer over the first light-emitting unit, and a second light-emitting unit over the charge-generation layer, for example.

Embodiment 5 can be referred to for the details of the structure and materials of the light-emitting device.

In FIG. 1B, the EL layers 113 included in the light-emitting devices are isolated from each other. When the EL layer is provided in an island shape for each light-emitting device, a leakage current between adjacent light-emitting devices can be inhibited. This can prevent crosstalk-induced unintended light emission, so that a display apparatus with extremely high contrast can be obtained. Specifically, a display apparatus having high current efficiency at low luminance can be obtained.

A material layer 113s that is formed in the same step as the EL layer 113 and has the same structure as the EL layer 113 is positioned over the insulating layer 255c. The material layer 113s is a layer that is split from the EL layer 113 in deposition of a layer forming the EL layer 113 to be independently provided over the insulating layer 255c.

Note that a region where the EL layer 113, the common electrode 115, and any of the pixel electrode 111R, the pixel electrode 111G, and the pixel electrode 111B overlap with each other can be referred to as a light-emitting region and is a region where EL emission is obtained. The light-emitting region and the region where the material layer 113s is provided are regions where PL (Photoluminescence) emission is obtained. Thus, the light-emitting region and the region where the material layer 113s is provided can be distinguished from each other by observing EL emission and PL emission.

A sidewall insulating layer 114 is provided in contact with the side surface of the pixel electrode 111R, the side surface of the pixel electrode 111G, and the side surface of the pixel electrode 111B. The sidewall insulating layer 114 can inhibit the common electrode 115 from being in contact with any of the pixel electrode 111R, the pixel electrode 111G, and the pixel electrode 111B. Hence, a short circuit of the light-emitting device is inhibited, and the reliability of the light-emitting device can be improved.

As the sidewall insulating layer 114, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

The sidewall insulating layer 114 may have either a single-layer structure or a stacked-layer structure.

There is no particular limitation on the method for forming the sidewall insulating layer 114. The sidewall insulating layer 114 can be formed, for example, by a sputtering method, a chemical vapor deposition (CVD) method, a plasma enhanced CVD (PECVD) method, or an atomic layer deposition (ALD) method. A sputtering method, a CVD method, or a PECVD method, which has a higher deposition rate than an ALD method, is particularly preferably employed, in which case the sidewall insulating layer 114 that is thick enough to ensure the insulating property can be formed with high productivity.

As the sidewall insulating layer 114, a silicon oxide film, a silicon nitride film, a silicon oxynitride film, or a silicon nitride oxide film is preferably used, for example. In that case, a highly reliable display apparatus can be manufactured with high productivity.

As the sidewall insulating layer 114, an aluminum oxide film may be formed by an ALD method. An ALD method enables the sidewall insulating layer 114 with high coverage to be formed.

In FIG. 1B, an insulating layer (also referred to as a partition, a bank, a spacer, or the like) that covers an end portion of the top surface of the pixel electrode 111R is not provided between the pixel electrode 111R and the EL layer 113. An insulating layer that covers an end portion of the top surface of the pixel electrode 111G is not provided between the pixel electrode 111G and the EL layer 113. Similarly, an insulating layer that covers an end portion of the top surface of the pixel electrode 111B is not provided between the pixel electrode 111B and the EL layer 113. This allows the distance between adjacent light-emitting regions to be extremely short. As a result, a display apparatus with high resolution or high definition can be obtained. In addition, a mask for forming the insulating layer is not needed, which leads to a reduction in manufacturing cost of the display apparatus.

Furthermore, light emitted from the EL layer can be extracted efficiently with a structure where an insulating layer that covers part of the top surface (also referred to as an end portion of the top surface) of the pixel electrode is not provided between the pixel electrode and the EL layer, i.e., a structure where an insulating layer is not provided between the pixel electrode and the EL layer. Therefore, the viewing angle dependence of the display apparatus of one embodiment of the present invention can be extremely small. A reduction in the viewing angle dependence leads to an increase in visibility of an image on the display apparatus. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction.

In FIG. 1B, the EL layers 113 are formed to cover the entire top surfaces of the pixel electrode 111R, the pixel electrode 111G, and the pixel electrode 111B. Such a structure enables the entire top surface of the pixel electrode to be a light-emitting region. Furthermore, the aperture ratio can be easily increased as compared with the structure where the insulating layer that covers part of the top surface of the pixel electrode is provided.

The common electrode 115 is shared by the light-emitting device 130R, the light-emitting device 130G, and the light-emitting device 130B. The common electrode 115 shared by the plurality of light-emitting devices is electrically connected to a conductive layer 123 provided in the connection portion 140 (see FIG. 2). As the conductive layer 123, a conductive layer formed using the same material in the same step as the pixel electrode 111R, the pixel electrode 111G, and the pixel electrode 111B is preferably used.

Note that the conductive layer 123 and the common electrode 115 are directly connected to each other in FIG. 2. For example, by using a mask for specifying a film formation area (also referred to as an area mask or a rough metal mask to be distinguished from a fine metal mask), the EL layer 113 and the common electrode 115 can be formed in different regions.

In FIG. 1B, the insulating layer 125 is provided to cover a region between adjacent light-emitting devices, specifically, the side surfaces and end portions of the top surfaces of the EL layers 113, parts of the side surfaces of the adjacent sidewall insulating layers 114, and the top surface of the material layer 113s. In other words, the insulating layer 125 is provided in a non-light-emitting region or has an opening in a portion overlapping with the light-emitting region.

In FIG. 1B, one end portion of the insulating layer 125 is positioned on the top surface of one of the adjacent EL layers 113 and the other end portion of the insulating layer 125 is positioned on the top surface of the other of the adjacent EL layers 113. Here, the end portion of the insulating layer 125 preferably overlaps with the EL layer 113 and the pixel electrode 111R (the pixel electrode 111G or the pixel electrode 111B). In that case, the end portion of the insulating layer 125 is more likely to be formed on a substantially flat surface of the EL layer 113.

The side surface of the EL layer 113 is covered with the insulating layer 125. The insulating layer 127 overlaps with the side surface of the EL layer 113 with the insulating layer 125 therebetween.

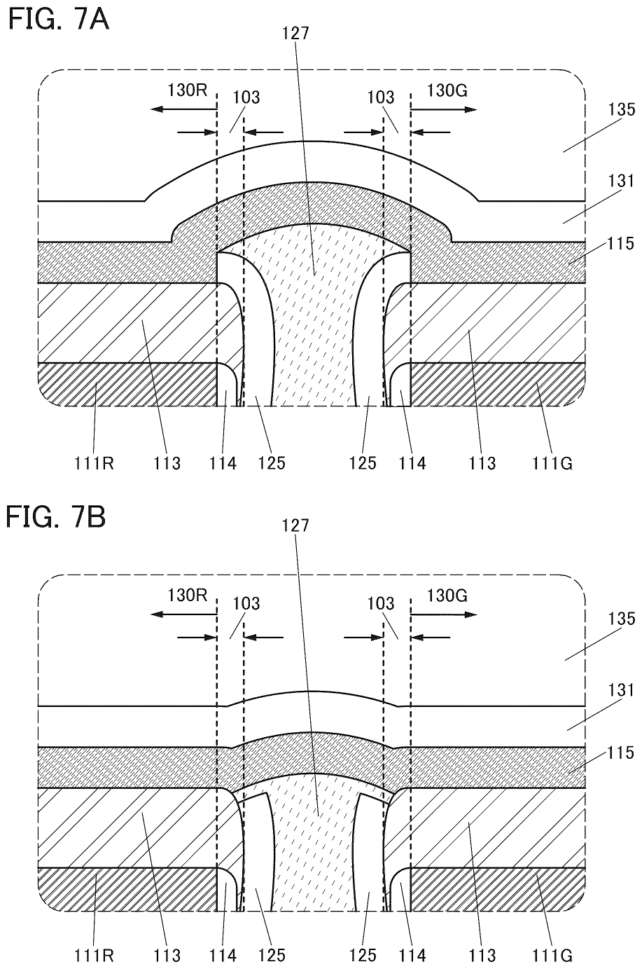

Part of the top surface of the EL layer 113 is covered with the insulating layer 125. The insulating layer 127 overlaps with part of the top surface of the EL layer 113 with the insulating layer 125 therebetween. Note that the top surface of the EL layer 113 is not limited to the top surface of a flat portion overlapping with the top surface of the pixel electrode but can include the top surface of a region positioned on the outer side of the top surface of the pixel electrode (see a region 103 in FIG. 7A).

The side surface and part of the top surface of the EL layer 113 are covered with at least one of the insulating layer 125 and the insulating layer 127, so that the common electrode 115 can be inhibited from being in contact with the side surfaces of the pixel electrode 111R, the pixel electrode 111G, the pixel electrode 111B, and the EL layer 113, inhibiting a short circuit of the light-emitting devices.

The insulating layer 125 is preferably in contact with the side surface and the end portion of the top surface of the EL layer 113. When the insulating layer 125 is in contact with the EL layer 113, separation of the EL layer 113 can be prevented. When the insulating layer 125 is in close contact with the adjacent EL layers 113, the effect of fixing or bonding the EL layers 113 and the like by the insulating layer 125 can be obtained.

The insulating layer 125 and the insulating layer 127 cover both the side surface and part of the top surface of the EL layer 113 as illustrated in FIG. 1B, whereby separation of the EL layer 113 can further be prevented.

The insulating layer 127 is provided over the insulating layer 125 to fill a depressed portion formed by the insulating layer 125. The insulating layer 127 can be configured to overlap with the side surface and part of the top surface of the EL layer 113 with the insulating layer 125 therebetween. The insulating layer 127 preferably covers at least part of the side surface of the insulating layer 125.

Providing the insulating layer 125 and the insulating layer 127 can fill a gap between adjacent island-shaped layers, whereby extreme unevenness of a formation surface of a layer (e.g., a carrier-injection layer and a common electrode) to be provided over the island-shaped layer can be reduced and the formation surface can be made flatter. Consequently, the coverage with the carrier-injection layer, the common electrode, and the like can be improved.

The common electrode 115 is provided over the EL layer 113, the insulating layer 125, and the insulating layer 127. Before the insulating layer 125 and the insulating layer 127 are provided, a step is generated between a region where the pixel electrode and the island-shaped EL layer are provided (a region where the light-emitting device is positioned) and a region where neither the pixel electrode nor the island-shaped EL layer is provided (a region between the light-emitting devices). By providing the insulating layer 125 and the insulating layer 127 in the display apparatus of one embodiment of the present invention, the step can be eliminated and the coverage with the common electrode 115 can be improved. Consequently, a connection defect due to disconnection of the common electrode 115 can be inhibited. In addition, an increase in electric resistance of the common electrode 115, which is caused by local thinning of the common electrode 115 due to the step, can be inhibited.

The top surface of the insulating layer 127 preferably has a shape with higher flatness; however, it may have a projecting portion, a convex surface, a concave surface, or a depressed portion. For example, the top surface of the insulating layer 127 preferably has a smooth convex shape with high flatness.

Next, examples of materials for the insulating layer 125 and the insulating layer 127 are described.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high etching selectivity with the EL layer and has a function of protecting the EL layer during formation of the insulating layer 127 described later. In particular, an inorganic insulating film such as an aluminum oxide film, a hafnium oxide film, or a silicon oxide film formed by an ALD method is used as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as low permeability). Alternatively, a barrier property means a function of capturing or fixing (also referred to as gettering) a particular substance.

When the insulating layer 125 has a function of a barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. In that case, deterioration of the EL layer due to entry of impurities from the insulating layer 125 into the EL layer can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling extreme unevenness of the insulating layer 125, which is formed between adjacent light-emitting devices. In other words, the insulating layer 127 has an effect of improving the flatness of the formation surface of the common electrode 115.

As the insulating layer 127, an insulating layer containing an organic material can be suitably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used as the photosensitive resin. As the photosensitive organic resin, either a positive material or a negative material may be used.

A material absorbing visible light may be used for the insulating layer 127. When the insulating layer 127 absorbs light emitted from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include a material containing a pigment of black or the like, a material containing a dye, a resin material with a light-absorbing property (e.g., polyimide), and a resin material that can be used for a color filter (a color filter material). A resin material obtained by stacking or mixing color filter materials of two or three or more colors is particularly preferably used, in which case the effect of blocking visible light can be enhanced. In particular, mixing color filter materials of three or more colors enables the formation of a black or nearly black resin layer.

As a result of the above effects, the display quality of the display apparatus of one embodiment of the present invention can be improved. In addition, the reliability of the light-emitting device can be improved. Moreover, the manufacturing yield of the light-emitting devices can be further increased.

In the region 150A illustrated in FIG. 1B and FIG. 3A, the island-shaped EL layer 113 is provided over the pixel electrode 111G, the island-shaped EL layer 113 is provided over the pixel electrode 111B, and the material layer 113s is provided over the insulating layer 255c. The EL layer 113 over the pixel electrode 111G, the EL layer 113 over the pixel electrode 111B, and the material layer 113s are isolated from each other.

The EL layers are separately formed for the light-emitting devices in this manner, whereby generation of crosstalk between adjacent subpixels can be inhibited.

Here, a structure of the sidewall insulating layer 114 that is preferable for locally thinning the EL layer 113 and splitting the EL layer 113 in a self-aligned manner in deposition of the EL layer 113 is described.

Height T1 of the sidewall insulating layer 114 shown in FIG. 3A is preferably greater than or equal to 0.5 times, further preferably greater than or equal to 0.8 times, still further preferably greater than or equal to 1 time, and yet still further preferably greater than or equal to 1.5 times the thickness of the EL layer 113.

As the height T1 of the sidewall insulating layer 114, the thickness of the sidewall insulating layer 114 in a direction perpendicular to the substrate surface is preferably used. Note that in FIG. 3A, the height T1 of the sidewall insulating layer 114 can be regarded as the sum of the thickness of the pixel electrode and the depth of the depressed portion provided in the insulating layer 255c.

As illustrated in FIG. 3A, a thickness T2 of the EL layer 113 in a region overlapping with the top surface of the pixel electrode is preferably used as the thickness of the EL layer 113.

The angle formed between the substrate surface and at least part of the surface of the sidewall insulating layer 114 that is in contact with the EL layer 113 (e.g., the side surface) is preferably 90° or substantially 90°. The angle can also be referred to as the angle formed between part of the surface of the sidewall insulating layer 114 that in contact with the EL layer 113 (e.g., the side surface) and the bottom surface. The angle is preferably greater than or equal to 60°, further preferably greater than or equal to 80°, still further preferably greater than or equal to 85°, and preferably less than or equal to 140°, further preferably less than or equal to 110°, still further preferably less than or equal to 100°, yet still further preferably less than or equal to 95°.

In order to make the angle within the above numerical range, the angle formed between the side surface of the pixel electrode and the substrate surface is preferably 90° or substantially 90°. The angle formed between the side surface of the pixel electrode and the substrate surface is preferably greater than or equal to 60°, further preferably greater than or equal to 80°, still further preferably greater than or equal to 85°, and preferably less than or equal to 140°, further preferably less than or equal to 110°, still further preferably less than or equal to 100°, yet still further preferably less than or equal to 95°.

The region 150B illustrated in FIG. 3B and the region 150C illustrated in FIG. 3C are examples where the EL layer 113 is provided to cover the pixel electrode 111G, the sidewall insulating layer 114, the insulating layer 255c, and the pixel electrode 111B.

A region 113t illustrated in FIG. 3B is a portion where the thickness of the EL layer 113 is smaller than that of the other portions of the EL layer 113.

Note that the thickness of the EL layer 113 in the region 113t refers not to the thickness in a direction perpendicular to a reference surface such as the substrate surface but to the thickness in a direction normal to the formation surface. Thus, in the case where the formation surface has unevenness, the direction that defines the thickness varies depending on the position. For example, the thickness of the EL layer 113 in the region 113t can be regarded as the thickness in a direction normal to the side surface of the sidewall insulating layer 114.

In the case where the EL layer 113 is locally thinned as described above, the electric resistance of the thinned portion is higher than that of the other portion, so that leakage current between adjacent light-emitting devices can be reduced. Thus, even when the EL layer 113 is continuous between adjacent light-emitting devices as illustrated in FIG. 3B and FIG. 3C, generation of crosstalk between adjacent subpixels can be inhibited.

The structure of the region 150C illustrated in FIG. 3C is different from that of the region 150B in that the insulating layer 255c does not have a depressed portion between two adjacent light-emitting devices.

The region 150D illustrated in FIG. 3D is an example where the insulating layer 255c has two depressed portions, a shallow depressed portion and a deep depressed portion, between two adjacent light-emitting devices.

A depressed portion may be formed in the insulating layer 255c in the processing of a conductive film to be the pixel electrode. Furthermore, a depressed portion may be formed in the insulating layer 255c in the processing of an insulating film to be the sidewall insulating layer 114. Thus, a shallow depressed portion and a deep depressed portion are provided. In FIG. 3D, the sidewall insulating layer 114 is on and in contact with the shallow depressed portion, and the material layer 113s is on and in contact with the deep depressed portion

Note that distance TO between the surface of the deep depressed portion of the insulating layer 255c and the bottom surface of the sidewall insulating layer 114 in FIG. 3D is also a parameter that affects local thinning of the EL layer 113 or split of the EL layer 113.

For the same reason as above, the sum of the distance TO and the height T1 of the sidewall insulating layer 114 is preferably greater than or equal to 0.5 times, further preferably greater than or equal to 0.8 times, still further preferably greater than or equal to 1 time, and yet still further preferably greater than or equal to 1.5 times the thickness of the EL layer 113, for example.

Note that in FIG. 3D, the sum of the distance TO and the height T1 of the sidewall insulating layer 114 can be regarded as the sum of the thickness of the pixel electrode and the depth of the depressed portion provided in the insulating layer 255c.

As described above, in the display apparatus of one embodiment of the present invention, the sidewall insulating layer 114 provided in contact with the side surface of the pixel electrode can inhibit contact between the pixel electrode and the common electrode 115, so that a short circuit of the light-emitting device can be prevented. Furthermore, by employing preferable height and shape of the sidewall insulating layer 114 for local thinning of the EL layer 113 or split of the EL layer 113, generation of crosstalk between adjacent subpixels can be inhibited.

Accordingly, it can also be said that the display apparatus of one embodiment of the present invention has a structure in which the EL layer 113 is intentionally disconnected.

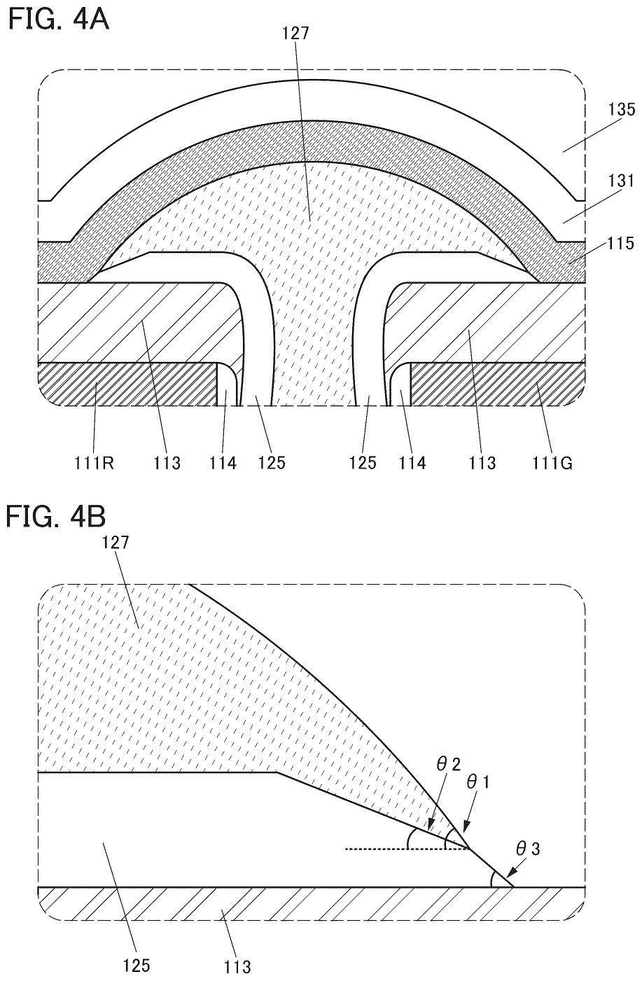

Next, a structure of the insulating layer 127 and the vicinity thereof will be described with reference to FIG. 4A and FIG. 4B. FIG. 4A is an enlarged cross-sectional view of a region including the insulating layer 127 between the light-emitting device 130R in the subpixel emitting red light and the light-emitting device 130G in the subpixel emitting green light, and the vicinity of the insulating layer 127. Although the insulating layer 127 between the light-emitting device 130R and the light-emitting device 130G adjacent to each other is described below as an example, the same applies to the insulating layer 127 between the light-emitting device 130G and the light-emitting device 130B. FIG. 4B is an enlarged view of the vicinity of an end portion of the insulating layer 127 over the EL layer 113 illustrated in FIG. 4A. Note that the common electrode 115 and the protective layer 131 are not illustrated in FIG. 4B.

As illustrated in FIG. 4A, the EL layer 113 is provided to cover the pixel electrode 111R and the sidewall insulating layer 114, and the EL layer 113 is provided to cover the pixel electrode 111G and the sidewall insulating layer 114. The insulating layer 125 is provided in contact with the side surface and part of the top surface of the EL layer 113. The insulating layer 127 is provided in contact with the top surface of the insulating layer 125. The insulating layer 127 overlaps with the side surface and part of the top surface of the EL layer 113 with the insulating layer 125 therebetween and is in contact with at least part of the side surface of the insulating layer 125. The common electrode 115 is provided to cover the EL layer 113, the insulating layer 125, and the insulating layer 127, and the protective layer 131 is provided over the common electrode 115.

The insulating layer 127 is formed in a region between two island-shaped EL layers (e.g., a region between two EL layers 113 in FIG. 4A). In this case, at least part of the insulating layer 127 is positioned between an end portion of the side surface of one of the EL layers and an end portion of the side surface of the other of the EL layers. Providing the insulating layer 127 in such a manner can prevent the common electrode 115 formed over the island-shaped EL layer and the insulating layer 127 from being split and locally thinned.

As illustrated in FIG. 4B, the end portion of the insulating layer 127 preferably has a tapered shape with a taper angle θ1 in the cross-sectional view of the display apparatus. The taper angle θ1 is an angle formed by the side surface (or end portion) of the insulating layer 127 and the substrate surface. Note that the taper angle θ1 is not limited to the angle with the substrate surface but may be an angle formed by the side surface (or end portion) of the insulating layer 127 and the top surface of a flat portion of the EL layer 113 or the top surface of a flat portion of the pixel electrode 111G.

The taper angle θ1 of the insulating layer 127 is less than 90°, preferably less than or equal to 60°, further preferably less than or equal to 45°, still further preferably less than or equal to 20°. When the end portion of the insulating layer 127 has such a tapered shape, the common electrode 115 can be formed with high coverage over the insulating layer 127, thereby inhibiting generation of disconnection or local thinning of the common electrode 115, for example. Consequently, the in-plane uniformity of the thickness of the common electrode 115 can be improved, leading to improved display quality of the display apparatus.

As illustrated in FIG. 4A, the top surface of the insulating layer 127 preferably has a convex shape in the cross-sectional view of the display apparatus. The convex shape of the top surface of the insulating layer 127 is preferably a shape gently bulging toward the center. The insulating layer 127 preferably has a shape such that the convex portion in the center of the top surface is connected continuously to a tapered portion in the end portion. When the insulating layer 127 has such a shape, the common electrode 115 can be formed with high coverage over the whole insulating layer 127.

As illustrated in FIG. 4B, the end portion (inclined portion) of the insulating layer 125 that overlaps with the insulating layer 127 preferably has a tapered shape with a taper angle θ2 in the cross-sectional view of the display apparatus. The taper angle θ2 is an angle formed by the side surface of the end portion and the substrate surface. Note that the taper angle θ2 is not limited to the angle with the substrate surface but may be an angle formed by the side surface of the end portion and the top surface of a flat portion of the EL layer 113 or the top surface of a flat portion of the pixel electrode 111G.

The taper angle θ2 of the insulating layer 125 is less than 90°, preferably less than or equal to 60°, further preferably less than or equal to 45°, still further preferably less than or equal to 20°.

As illustrated in FIG. 4B, the end portion (inclined portion) of the insulating layer 125 that does not overlap with the insulating layer 127 preferably has a tapered shape with a taper angle θ3 in the cross-sectional view of the display apparatus. The taper angle θ3 is an angle formed by the side surface of the end portion and the substrate surface. Note that the taper angle θ3 is not limited to the angle with the substrate surface but may be an angle formed by the side surface of the end portion and the top surface of a flat portion of the EL layer 113 or the top surface of a flat portion of the pixel electrode 111G.

The taper angle θ3 of the insulating layer 125 is less than 90°, preferably less than or equal to 60°, further preferably less than or equal to 45°, still further preferably less than or equal to 20°. When the insulating layer 125 has such a tapered shape, the common electrode 115 can be formed with high coverage over the insulating layer 125.

Although the details will be described in Embodiment 2, when an insulating film to be the insulating layer 125 is etched at a time, the insulating layer 125 under the end portion of the insulating layer 127 may be eliminated by side etching and a cavity may be formed accordingly. The cavity causes unevenness on the formation surface of the common electrode 115; hence disconnection of the common electrode 115 is more likely to be caused. Thus, the etching treatment is performed in two separate steps and heat treatment is performed therebetween, whereby even when a cavity is formed by the first etching treatment, the cavity can be filled with the insulating layer 127 deformed by the heat treatment. Since the second etching treatment etches a thin film, the amount of side etching is small; thus, a cavity is less likely to be formed or can be extremely small even when formed. Thus, unevenness can be inhibited from being formed on the formation surface of the common electrode 115, and disconnection of the common electrode 115 can be inhibited. Since the etching treatment is performed twice in this manner, the taper angle θ2 and the taper angle θ3 are different from each other in some cases. The taper angle θ2 and the taper angle θ3 may be the same. Furthermore, the taper angle θ2 and the taper angle θ3 may each be smaller than the taper angle θ1.

Although the example in which the etching treatment is performed on the insulating film to be the insulating layer 125 in two separate steps is described above, one embodiment of the present invention is not limited thereto. The etching treatment may be performed at a time on the insulating film to be the insulating layer 125 depending on the thickness of the insulating film to be the insulating layer 125 or the etching treatment conditions.

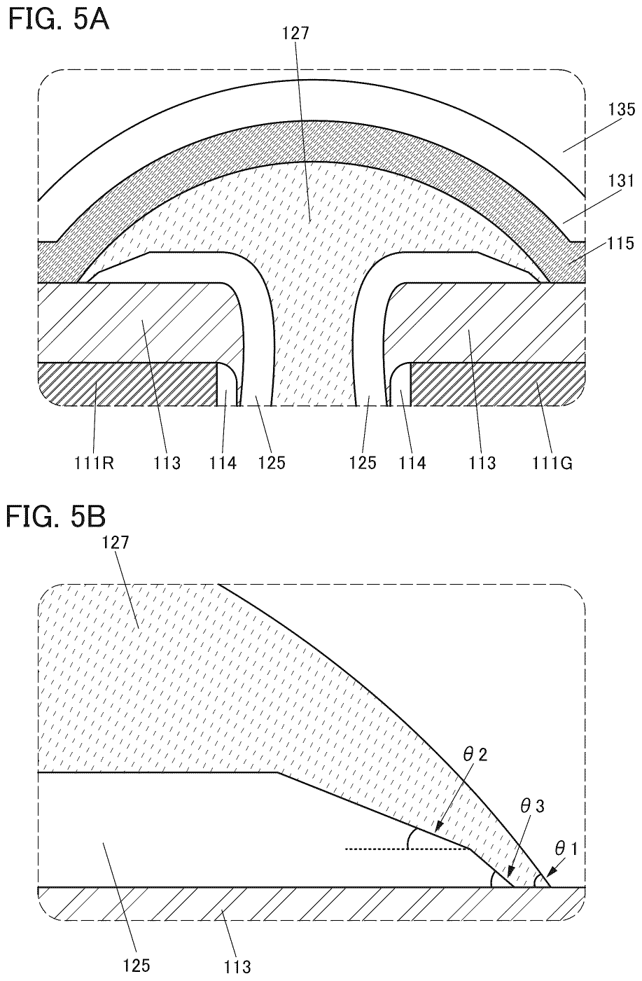

FIG. 5A and FIG. 5B illustrate an example in which the insulating layer 127 covers the entire side surface of the insulating layer 125. Specifically, in FIG. 5B, the insulating layer 127 touches and covers both of the two inclined surfaces. This is preferable because unevenness of the formation surface of the common electrode 115 can be further reduced. FIG. 5B illustrates an example where the end portion of the insulating layer 127 is positioned on the outer side of the end portion of the insulating layer 125. As illustrated in FIG. 4B, the end portion of the insulating layer 127 may be positioned on the inner side of the end portion of the insulating layer 125, or may be aligned or substantially aligned with the end portion of the insulating layer 125. As illustrated in FIG. 5B, the insulating layer 127 may be in contact with the EL layer 113.

Also in FIG. 5B, the taper angle θ1 to the taper angle θ3 are preferably within the above range.

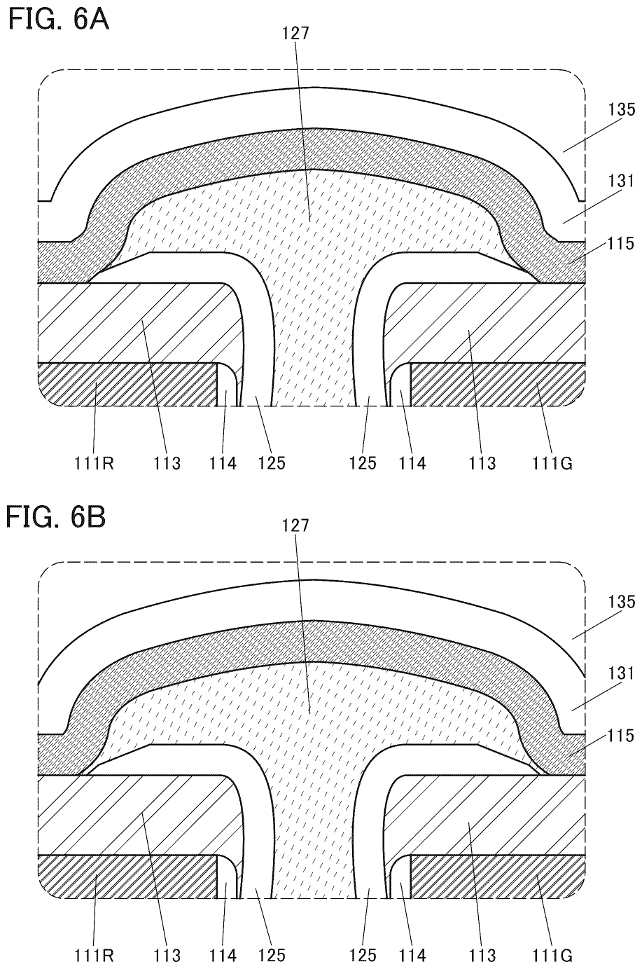

FIG. 6A and FIG. 6B illustrate an example where the side surface of the insulating layer 127 has a concave shape (also referred to as a narrowed portion, a depressed portion, a dent, a hollow, or the like). Depending on the material and formation conditions (e.g., heating temperature, heating time, and heating atmosphere) of the insulating layer 127, the side surface of the insulating layer 127 has a concave shape in some cases.

FIG. 6A illustrates an example where part of the side surface of the insulating layer 125 is covered with the insulating layer 127 and the other part of the side surface of the insulating layer 125 is exposed. FIG. 6B illustrates an example where the insulating layer 127 touches and covers the entire side surface of the insulating layer 125.

As illustrated in FIG. 4 to FIG. 6, one end portion of the insulating layer 127 preferably overlaps with the top surface of the pixel electrode 111R and the other end portion of the insulating layer 127 preferably overlaps with the top surface of the pixel electrode 111G. Such a structure enables the end portion of the insulating layer 127 to be formed over a substantially flat region of the EL layer 113. Thus, it becomes relatively easy to form tapered shapes of the insulating layer 127 and the insulating layer 125. In addition, film separation between the EL layer 113 and the pixel electrode 111R or the pixel electrode 111G can be inhibited. Meanwhile, a portion where the top surface of the pixel electrode and the insulating layer 127 overlap with each other is preferably smaller, in which case a light-emitting region of the light-emitting device can be wider and the aperture ratio can be higher.

Note that the insulating layer 127 does not necessarily overlap with the top surface of the pixel electrode. As illustrated in FIG. 7A, the insulating layer 127 does not necessarily overlap with the top surface of the pixel electrode, and in a plan view, the position of one end portion of the insulating layer 127 may be substantially aligned with the position of the side surface of the pixel electrode 111R and the position of the other end portion of the insulating layer 127 may be substantially aligned with the position of the side surface of the pixel electrode 111G. As illustrated in FIG. 7B, the insulating layer 127 does not necessarily overlap with the pixel electrode and may be provided in a region interposed between the pixel electrode 111R and the pixel electrode 111G. In FIG. 7A and FIG. 7B, part or the whole of the top surface of the EL layer 113 in the region (the region 103) positioned on the outer side of the top surface of the pixel electrode is covered with the insulating layer 125 and the insulating layer 127. Even such a structure can reduce unevenness of the formation surface of the common electrode 115 and improve the coverage with the common electrode 115, as compared with the structure where the insulating layer 125 and the insulating layer 127 are not provided. Note that the region 103 can be referred to as a dummy region.

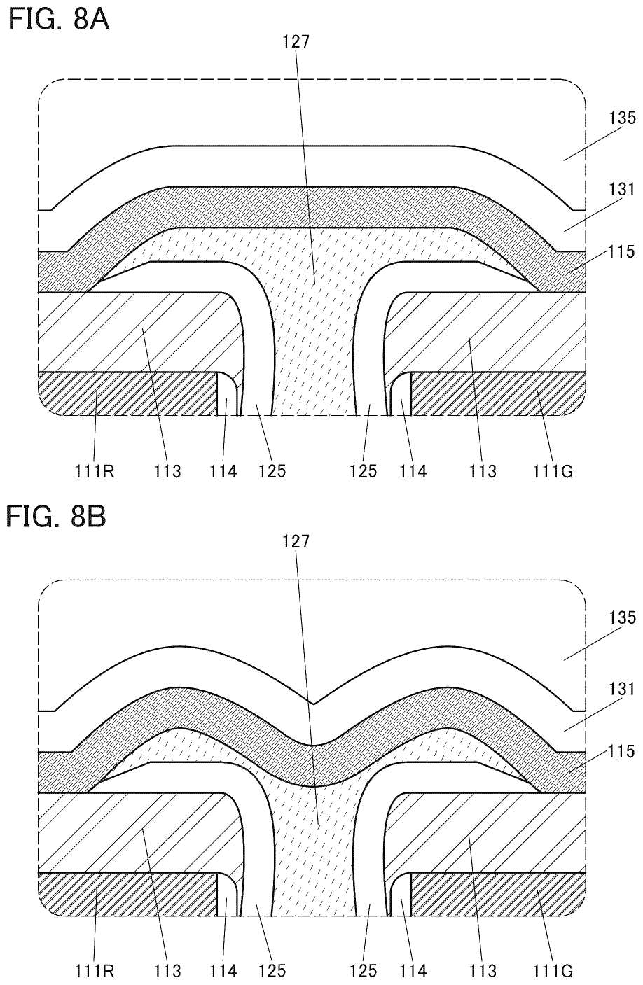

As illustrated in FIG. 8A, the top surface of the insulating layer 127 may have a flat portion in a cross-sectional view of the display apparatus.

As illustrated in FIG. 8B, the top surface of the insulating layer 127 may have a concave shape in a cross-sectional view of the display apparatus. In FIG. 8B, the top surface of the insulating layer 127 has a shape that gently bulges toward the center, i.e., a convex surface, and has a shape that is depressed in the center and its vicinity, i.e., a concave surface. In FIG. 8B, the insulating layer 127 has a shape such that the convex portion of the top surface is connected continuously to the tapered portion in the end portion. Even when the insulating layer 127 has such a shape, the common electrode 115 can be formed with high coverage over the whole insulating layer 127.

As a method for forming a concave surface in the center portion of the insulating layer 127 illustrated in FIG. 8B, light exposure using a multi-tone mask (typically, a half-tone mask or a gray-tone mask) can be given. A multi-tone mask is a mask capable of light exposure of three light-exposure levels to provide an exposed portion, a half-exposed portion, and an unexposed portion, and is a light-exposure mask through which light is transmitted to have a plurality of intensities. This enables the insulating layer 127 including regions with a plurality of (typically two kinds of) thicknesses to be formed with only one photomask (one light exposure and development process).

Note that a method for forming a concave surface in the center portion of the insulating layer 127 is not limited to the above method. For example, an exposed portion and a half-exposed portion may be formed separately with the use of two photomasks. Alternatively, the viscosity of a resin material used for the insulating layer 127 may be adjusted; specifically, the viscosity of a material used for the insulating layer 127 may be less than or equal to 10 cP, preferably greater than or equal to 1 cP and less than or equal to 5 cP.

As described above, in the structures illustrated in FIG. 4 to FIG. 8, providing the insulating layer 125 and the insulating layer 127 enables the common electrode 115 to be formed with favorable coverage. Moreover, the common electrode 115 can be prevented from being split and locally thinned. This can inhibit the common electrode 115 between light-emitting devices from having a connection defect due to the split portion and an increased electric resistance due to the locally thinned portion. Consequently, the display apparatus of one embodiment of the present invention can have improved display quality.

The protective layer 131 is preferably provided over the light-emitting device 130R, the light-emitting device 130G, and the light-emitting device 130B. Providing the protective layer 131 can improve the reliability of the light-emitting devices. The protective layer 131 may have either a single-layer structure or a stacked-layer structure of two or more layers.

There is no limitation on the conductivity of the protective layer 131. As the protective layer 131, at least one type of insulating films, semiconductor films, and conductive films can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the sidewall insulating layer 114. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

The protective layer 131 may have a stacked structure of two layers formed by different formation methods. Specifically, the first layer of the protective layer 131 may be formed by an ALD method, and the second layer of the protective layer 131 may be formed by a sputtering method.

The protective layer 131 may include an organic film. For example, the protective layer 131 may include both an organic film and an inorganic film.

The insulating layer 135 is preferably provided over the protective layer 131. As the insulating layer 135, a layer having a planarization function is preferably used. An organic film is preferably used as the insulating layer 135, in which case the flatness of the surface of the insulating layer 135 can be increased.

Examples of an organic material that can be used for the protective layer 131 or the protective layer 135 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. For the protective layer 131 or the protective layer 135, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

A light-blocking layer may be provided on the surface of the substrate 120 on the resin layer 122 side. Moreover, a variety of optical members can be provided on the outer side of the substrate 120 (the surface opposite to the resin layer 122 side). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer side of the substrate 120. For example, a glass layer or a silica layer (SiOₓ layer) is preferably provided as the surface protective layer, in which case generation of surface contamination and a scratch can be inhibited. For the surface protective layer, DLC (diamond like carbon), aluminum oxide (AlOₓ), a polyester-based material, a polycarbonate-based material, or the like may be used. For the surface protective layer, a material having a high visible light transmittance is preferably used. The surface protective layer is preferably formed using a material with high hardness.

For the substrate 120, glass, quartz, ceramic, sapphire, a resin, a metal, an alloy, a semiconductor, or the like can be used. The substrate through which light from the light-emitting device is extracted is formed using a material that transmits the light. When a flexible material is used for the substrate 120, the flexibility of the display apparatus can be increased. Furthermore, a polarizing plate may be used as the substrate 120.

For the substrate 120, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of the display apparatus might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

Note that the pixel electrode 111R, the pixel electrode 111G, and the pixel electrode 111B may have different thicknesses. Alternatively, as described later, optical adjustment layers with different thicknesses may be provided over the pixel electrode 111R, the pixel electrode 111G, and the pixel electrode 111B.

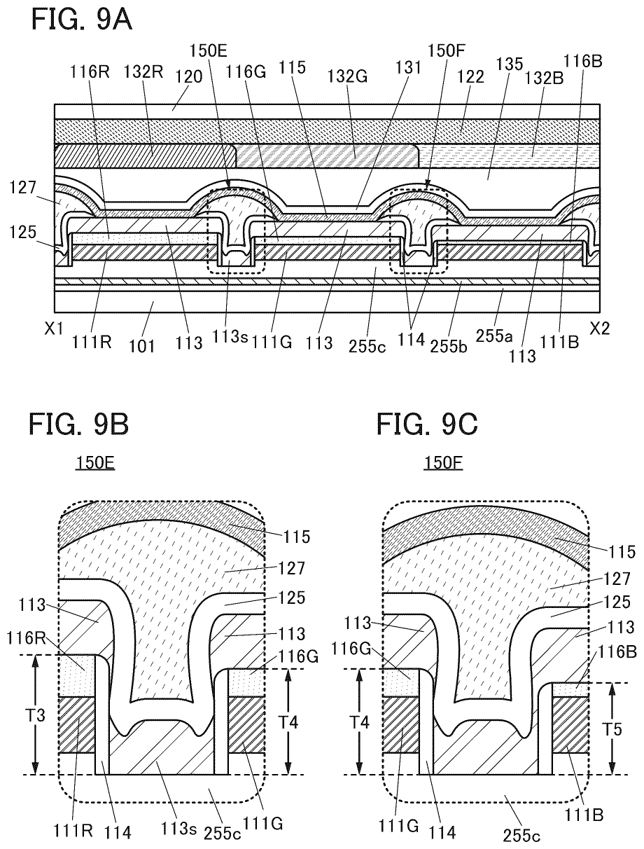

FIG. 9A illustrates a variation example of FIG. 1B. FIG. 9B and FIG. 9C are enlarged views of a region 150E and a region 150F illustrated in FIG. 9A.

In FIG. 9A, an optical adjustment layer 116R is provided over the pixel electrode 111R, an optical adjustment layer 116G is provided over the pixel electrode 111G, and an optical adjustment layer 116B is provided over the pixel electrode 111B.

FIG. 9A illustrates an example in which the thickness of the optical adjustment layer 116R is larger than that of the optical adjustment layer 116G and the thickness of the optical adjustment layer 116G is larger than that of the optical adjustment layer 116B. The thickness of each optical adjustment layer is preferably determined in the following manner: the thickness of the optical adjustment layer 116R is set to intensify red light, the thickness of the optical adjustment layer 116G is set to intensify green light, and the thickness of the optical adjustment layer 116B is set to intensify blue light. This achieves a microcavity structure, so that the color purity of light emitted from each light-emitting device can be increased.

The optical adjustment layer is preferably formed using a conductive material transmitting visible light among the conductive materials that can be used for the electrode of the light-emitting device.

In the region 150E illustrated in FIG. 9A and FIG. 9B, the island-shaped EL layer 113 is provided over the pixel electrode 111R with the optical adjustment layer 116R therebetween, the island-shaped EL layer 113 is provided over the pixel electrode 111G with the optical adjustment layer 116G therebetween, and the material layer 113s is provided over the insulating layer 255c. The EL layer 113 over the pixel electrode 111R, the EL layer 113 over the pixel electrode 111G, and the material layer 113s are isolated from each other.

In the region 150F illustrated in FIG. 9A and FIG. 9C, the island-shaped EL layer 113 is provided over the pixel electrode 111G with the optical adjustment layer 116G therebetween and the island-shaped EL layer 113 is provided to cover the insulating layer 255c, the sidewall insulating layer 114 (on the pixel electrode 111B side), the pixel electrode 111B, and the optical adjustment layer 116B. The EL layer 113 over the pixel electrode 111G and the EL layer 113 that covers the insulating layer 255c, the sidewall insulating layer 114 (on the pixel electrode 111B side), and the pixel electrode 111B are isolated from each other.

When the thickness of the optical adjustment layer varies depending on the subpixel, the height of the sidewall insulating layer 114 also varies depending on the subpixel in some cases. In FIG. 9B and FIG. 9C, height T3 of the sidewall insulating layer 114 covering the side surface of the pixel electrode 111R is larger than height T4 of the sidewall insulating layer 114 covering the side surface of the pixel electrode 111G and height T5 of the sidewall insulating layer 114 covering the side surface of the pixel electrode 111B, and the height T4 of the sidewall insulating layer 114 covering the side surface of the pixel electrode 111G is larger than the height T5 of the sidewall insulating layer 114 covering the side surface of the pixel electrode 111B.

As illustrated in FIG. 9C, depending on the value of the height T5, the EL layer 113 is not split by the sidewall insulating layer 114 covering the side surface of the pixel electrode 111B, and one island-shaped EL layer 113 includes a portion positioned over the insulating layer 255c, a portion covering the sidewall insulating layer 114 (on the pixel electrode 111B side), and a portion covering the top surface of the pixel electrode 111B. However, in FIG. 9C, the EL layer 113 is split by the sidewall insulating layer 114 covering the side surface of the pixel electrode 111G. That is, island-shaped EL layers are independently provided for adjacent light-emitting devices; thus, generation of crosstalk between adjacent subpixels can be inhibited.

Note that depending on the value of the height T4, the EL layer 113 is not split even by the sidewall insulating layer 114 covering the side surface of the pixel electrode 111G in some cases. That is, one island-shaped EL layer 113 may cover the insulating layer 255c, the sidewall insulating layer 114 in contact with the pixel electrode 111G, the top surface of the pixel electrode 111G, the sidewall insulating layer 114 in contact with the pixel electrode 111B, and the top surface of the pixel electrode 111B. In that case, a portion of the EL layer 113 that covers the sidewall insulating layer 114 is thinner than the other portions; thus, the electric resistance of the thinner portion is higher than that of the other portions, so that leakage current between adjacent light-emitting devices can be reduced. Accordingly, even when the EL layer 113 is continuous across adjacent light-emitting devices as described above, generation of crosstalk between adjacent subpixels can be inhibited.

The structure in which the EL layer 113 is formed in an island shape in some light-emitting devices and the EL layer 113 is formed as a continuous layer in the other light-emitting devices as described above is also one embodiment of the present invention. For example, the display apparatus of one embodiment of the present invention may include both the region 150A illustrated in FIG. 3A and the region 150B illustrated in FIG. 3B.

FIG. 1B and FIG. 9A each illustrate an example in which the coloring layer 132R, the coloring layer 132G, and the coloring layer 132B are directly provided over the light-emitting devices with the protective layer 131 and the protective layer 135 therebetween. With such a structure, the alignment accuracy of the light-emitting devices and the coloring layers can be improved. The distance between the light-emitting devices and the coloring layers are preferably reduced, in which case color mixing can be inhibited and the viewing angle characteristics can be improved.

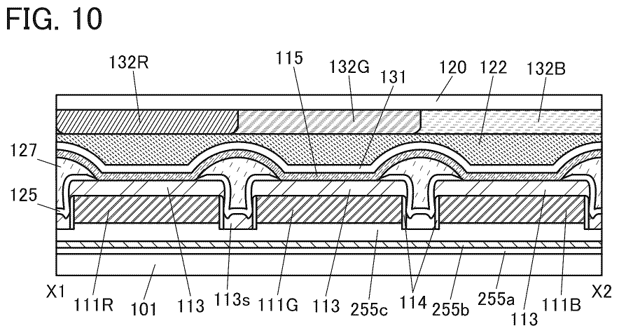

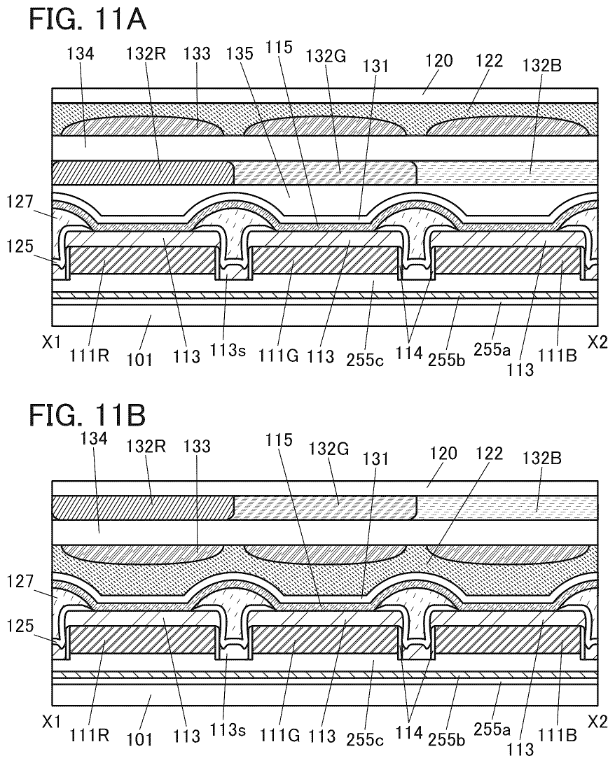

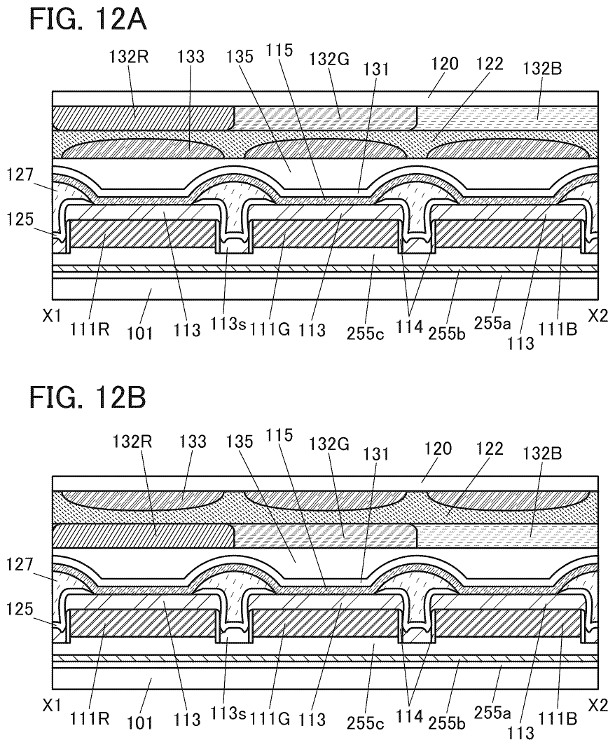

FIG. 10, FIG. 11A, FIG. 11B, FIG. 12A, and FIG. 12B illustrate variation examples of FIG. 1B.

As illustrated in FIG. 10, the substrate 120 provided with the coloring layer 132R, the coloring layer 132G, and the coloring layer 132B may be attached to the protective layer 131 with the resin layer 122. The coloring layer 132R, the coloring layer 132G, and the coloring layer 132B are provided on the substrate 120, whereby the temperature of heat treatment in the formation process of the coloring layer 132R, the coloring layer 132G, and the coloring layer 132B can be increased.

As illustrated in FIG. 11A and FIG. 11B, a lens 133 may be provided in the display apparatus. The lens 133 is preferably provided to overlap with the light-emitting device. By providing the lens 133, light emitted from the light-emitting device can be extracted to the outside of the display apparatus more efficiently than in the case where the lens 133 is not provided.

FIG. 11A illustrates an example in which the coloring layer 132R, the coloring layer 132G, and the coloring layer 132B are provided over the light-emitting devices with the protective layer 131 and the protective layer 135 therebetween, an insulating layer 134 is provided over the coloring layer 132R, the coloring layer 132G, and the coloring layer 132B, and the lens 133 is provided over the insulating layer 134. The coloring layer 132R, the coloring layer 132G, the coloring layer 132B, and the lens 133 are directly formed over the substrate provided with the light-emitting devices, whereby the alignment accuracy of the light-emitting devices and the coloring layers or the lens 133 can be improved.

For the insulating layer 134, one or both of an inorganic insulating film and an organic insulating film can be used. The insulating layer 134 may have either a single-layer structure or a stacked-layer structure. For the insulating layer 134, a material that can be used for the protective layer 131 can be used, for example. The insulating layer 134 preferably has a planarization function. Light emitted from the light-emitting device is extracted through the insulating layer 134, so that the insulating layer 134 preferably has a high visible-light-transmitting property.

In FIG. 11A, light emitted from the light-emitting device passes through the coloring layer and then passes through the lens 133, resulting in being extracted to the outside of the display apparatus. The distance between the light-emitting devices and the coloring layers are preferably reduced, in which case color mixing can be inhibited and the viewing angle characteristics can be improved. Note that the lens 133 may be provided over the light-emitting device and the coloring layer may be provided over the lens 133.

FIG. 11B illustrates an example in which the substrate 120 provided with the coloring layer 132R, the coloring layer 132G, the coloring layer 132B, and the lens 133 is attached onto the protective layer 131 with the resin layer 122. The substrate 120 is provided with the coloring layer 132R, the coloring layer 132G, the coloring layer 132B, and the lens 133, whereby the temperature of heat treatment in the formation process of these coloring layers can be increased.

FIG. 11B illustrates an example in which the coloring layer 132R, the coloring layer 132G, and the coloring layer 132B are provided in contact with the substrate 120, the insulating layer 134 is provided in contact with the coloring layer 132R, the coloring layer 132G, and the coloring layer 132B, and the lens 133 is provided in contact with the insulating layer 134.

In FIG. 11B, light emitted from the light-emitting device passes through the lens 133 and then passes through the coloring layer, resulting in being extracted to the outside of the display apparatus. Note that the lens 133 may be provided in contact with the substrate 120, the insulating layer 134 may be provided in contact with the lens 133, and the coloring layer may be provided in contact with the insulating layer 134. In that case, light emitted from the light-emitting device passes through the coloring layer and then passes through the lens 133, resulting in being extracted to the outside of the display apparatus.

As illustrated in FIG. 12A and FIG. 12B, either the lens or the coloring layer may be provided over the insulating layer 135 and the other may be provided on the substrate 120.

FIG. 12A illustrates an example in which the lens 133 is provided over the light-emitting devices with the protective layer 131 and the insulating layer 135 therebetween and the substrate 120 provided with the coloring layer 132R, the coloring layer 132G, and the coloring layer 132B is attached onto the lens 133 and the insulating layer 135 with the resin layer 122.

FIG. 12B illustrates an example in which the coloring layer 132R, the coloring layer 132G, and the coloring layer 132B are provided over the light-emitting devices with the protective layer 131 and the insulating layer 135 therebetween and the substrate 120 provided with the lens 133 is attached onto the coloring layer 132R, the coloring layer 132G, and the coloring layer 132B with the resin layer 122.

The lens 133 is preferably a lens that has a convex surface and a flat surface on the surface opposite to the convex surface (also referred to as a plano-convex lens). The convex surface of the lens 133 may face either the substrate 120 side or the light-emitting device side; however, in the case where the lens 133 is provided on the light-emitting device side as illustrated in FIG. 11A and FIG. 12A, the convex surface preferably faces the substrate 120 side in terms of ease of manufacture. By contrast, in the case where the lens 133 is provided on the substrate 120 side as illustrated in FIG. 11B and FIG. 12B, the convex surface preferably faces the light-emitting device side.

The lens 133 can be formed using at least one of an inorganic material and an organic material. For example, a material containing a resin can be used for the lens 133. Moreover, a material containing at least one of an oxide and a sulfide can be used for the lens 133. The lens 133 is preferably formed using a material having a higher refractive index than the resin layer 122. As the lens 133, a microlens array can be used, for example. The lens 133 may be directly formed over the substrate or the light-emitting device. Alternatively, a lens separately formed may be attached thereto.

Coloring layers of different colors preferably include a region where they overlap with each other. The region where the coloring layers of different colors overlap with each other can function as a light-blocking layer. This can further reduce reflection of external light.

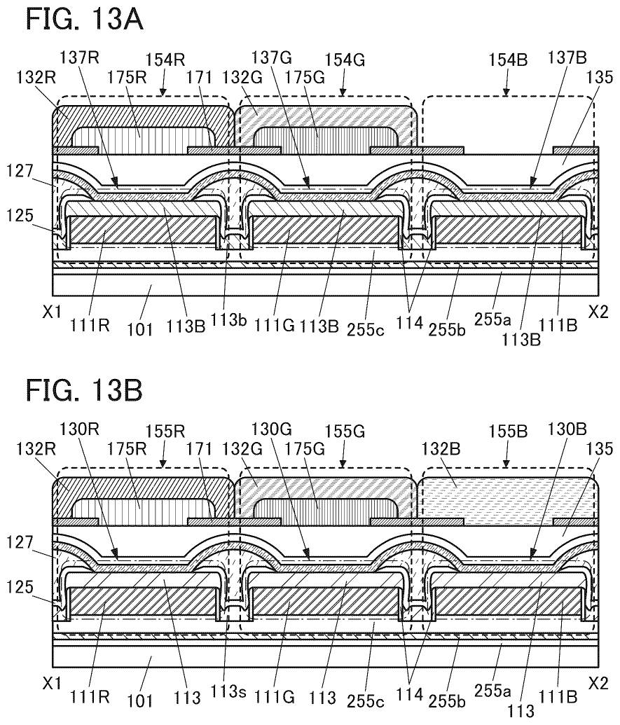

FIG. 13A is a schematic cross-sectional view of a display apparatus described below as an example. The display apparatus includes a subpixel 154R, a subpixel 154G, and a subpixel 154B.

The subpixel 154R, the subpixel 154G, and the subpixel 154B include a light-emitting device 137R, a light-emitting device 137G, and a light-emitting device 137B, respectively. The light-emitting device 137R, the light-emitting device 137G, and the light-emitting device 137B are different from the light-emitting device 130R, the light-emitting device 130G, and the light-emitting device 130B in including not the EL layer 113 but an EL layer 113B. In a region between the pixel electrode 111R and the pixel electrode 111G, a material layer 113b is provided over the insulating layer 255c. Similarly, the material layer 113b is provided over the insulating layer 255c also in a region between the pixel electrode 111G and the pixel electrode 111B and a region between the pixel electrode 111B and the pixel electrode 111R. The material layer 113b is formed in the same step as the EL layer 113B, has the same structure as the EL layer 113B, and corresponds to the material layer 113s illustrated in FIG. 1B and the like. The EL layer 113B contains a light-emitting material that emits blue light, violet light, or ultraviolet light. Thus, the light-emitting device 137R, the light-emitting device 137G, and the light-emitting device 137B each emit blue light, violet light, or ultraviolet light.

The subpixel 154R includes a color conversion layer 175R and the coloring layer 132R on the optical path of light emitted from the light-emitting device 137R. The color conversion layer 175R has a function of absorbing light emitted from the light-emitting device 137R and emitting red light.

The subpixel 154G includes a color conversion layer 175G and the coloring layer 132G on the optical path of light emitted from the light-emitting device 137G. The color conversion layer 175G has a function of absorbing light emitted from the light-emitting device 137G and emitting green light.

The light-emitting device 137B is provided in the subpixel 154B. Note that in the case where a light-emitting device that emits violet light or ultraviolet light is used as the light-emitting device 137B, either one or both of a coloring layer that transmits blue light and a color conversion layer that absorbs light emitted from the light-emitting device 137B and emits blue light are preferably provided on the optical path of the light-emitting device 137B.

For each of the color conversion layer 175R and the color conversion layer 175G, a fluorescent material, a phosphorescent material, a resin material where quantum dots are dispersed, or the like can be used, for example.

The coloring layer 132R and the coloring layer 132G each have a function of absorbing blue or violet light that has passed through the color conversion layers. This can increase the color purity of light emitted from the subpixels, so that a display apparatus with higher display quality can be achieved. Note that a coloring layer that transmits blue light may be provided in the subpixel 154B.

A display apparatus illustrated in FIG. 13B includes a subpixel 155R, a subpixel 155G, and a subpixel 155B.

The subpixel 155R includes the light-emitting device 130R, the color conversion layer 175R, and the coloring layer 132R. As described above, the light-emitting device 130R is a light-emitting device that emits white light. The color conversion layer 175R has a function of absorbing light having a shorter wavelength than red light among white light emitted from the light-emitting device 130R and emitting red light. The coloring layer 132R has a function of transmitting red light and absorbing visible light of the other colors.

The subpixel 155G includes the light-emitting device 130G, the color conversion layer 175G, and the coloring layer 132G. As described above, the light-emitting device 130G is a light-emitting device that emits white light. The color conversion layer 175G has a function of absorbing light having a shorter wavelength than green light among white light emitted from the light-emitting device 130G and emitting green light. The coloring layer 132G has a function of transmitting green light and absorbing visible light of the other colors.

The subpixel 155B includes the light-emitting device 130B and the coloring layer 132B. As described above, the light-emitting device 130B is a light-emitting device that emits white light. The coloring layer 132B has a function of transmitting blue light among white light emitted from the light-emitting device 130B and absorbing visible light of the other colors.

The color conversion layers are used in the red and green subpixels in this manner, whereby light that would normally be absorbed by the coloring layers among the light emitted from the white light-emitting devices can be reused; thus, the emission efficiency can be improved as compared with a structure where the color conversion layer is not used.

Note that FIG. 13A and FIG. 13B illustrate an example in which a light-blocking layer 171 is provided in a portion over the insulating layer 135 that overlaps with the insulating layer 127. The light-blocking layer 171 is preferably provided between adjacent light-emitting devices in a plan view. With such a structure, light that is mixed between adjacent color conversion layers, for example, can be blocked by the light-blocking layer 171, so that the mixed light can be prevented from being emitted to the outside. The light-blocking layer 171 preferably contains a material absorbing at least part of visible light. For example, the light-blocking layer 171 itself may be formed of a material absorbing visible light (e.g., a colored organic material or a colored inorganic material), or the light-blocking layer 171 may contain a pigment absorbing visible light. For example, for the light-blocking layer 171, a resin that contains carbon black as a pigment and functions as a black matrix; a resin that can be used as a color filter transmitting red, blue, or green light and absorbing other light; or the like can be used.

Note that the display apparatus of one embodiment of the present invention does not necessarily include the light-blocking layer 171. In that case, as illustrated in FIG. 1B and the like, adjacent coloring layers preferably include a region where their end portions overlap with each other.

In the display apparatus of one embodiment of the present invention, the EL layer is locally thinned or the island-shaped EL layer is provided for each light-emitting device, whereby generation of leakage current between subpixels can be inhibited. This can prevent crosstalk-induced unintended light emission, so that a display apparatus with extremely high contrast can be obtained.

In the display apparatus of one embodiment of the present invention, the sidewall insulating layer is provided on the side surface of the pixel electrode. This can inhibit a short circuit of the light-emitting device, resulting in a highly reliable display apparatus.

Furthermore, in the display apparatus of one embodiment of the present invention, the insulating layer is provided to cover at least the side surface and part of the top surface of the island-shaped EL layer. Then, the common electrode is provided to cover the insulating layer and the EL layer. Thus, disconnection of the common electrode due to a step between adjacent pixel electrodes can be inhibited, and the manufacturing yield of the light-emitting devices can further be increased.

This embodiment can be combined with any of the other embodiments as appropriate. In this specification, in the case where a plurality of structure examples are described in one embodiment, the structure examples can be combined as appropriate.

### Embodiment 2

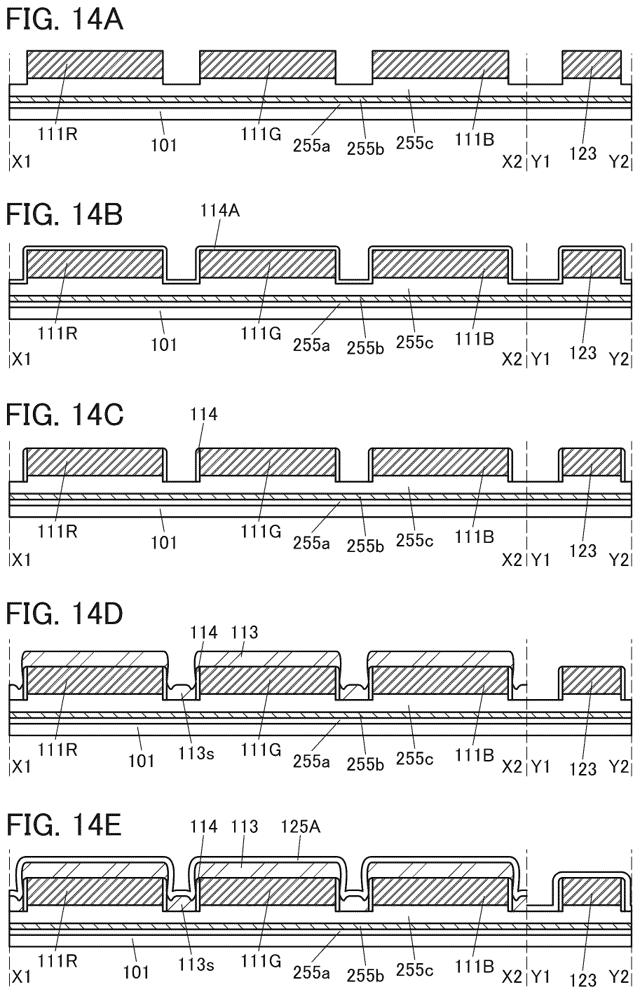

In this embodiment, a method of manufacturing a display apparatus of one embodiment of the present invention will be described with reference to FIG. 14 to FIG. 16. Note that as for a material and a formation method of each component, portions similar to the portions described in Embodiment 1 are not described in some cases. The structure of the light-emitting device will be described in detail in Embodiment 5.

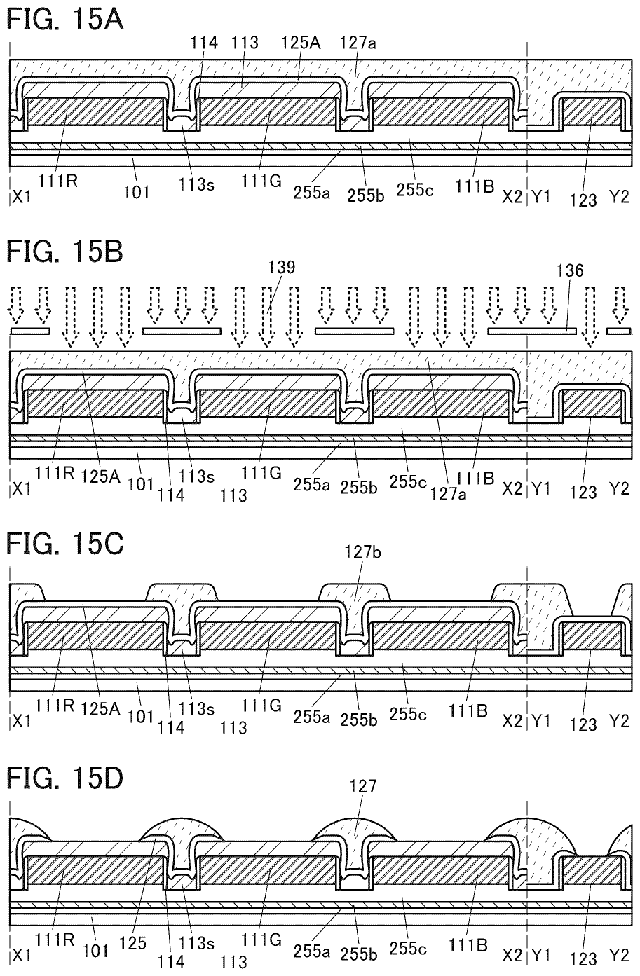

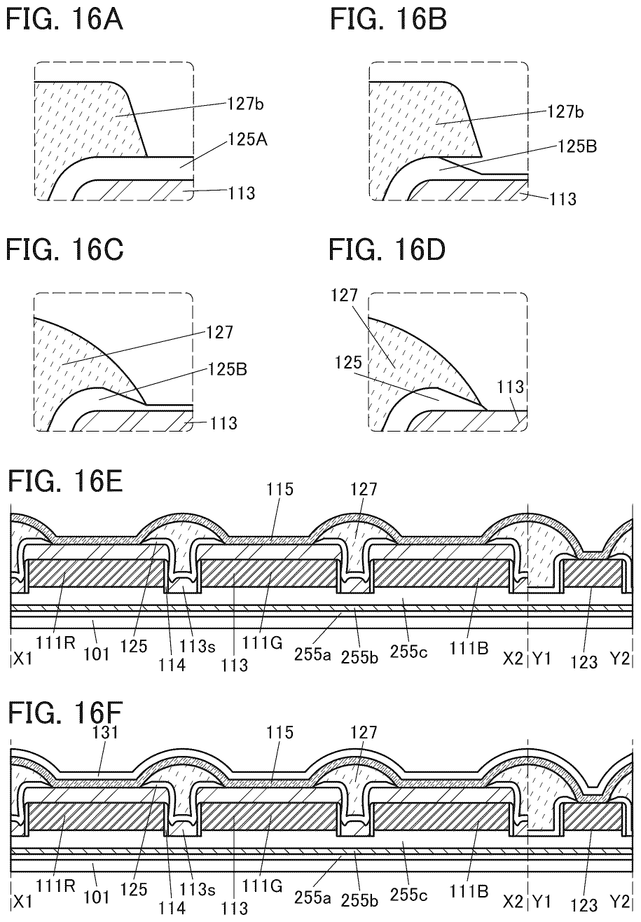

FIG. 14A to FIG. 14E, FIG. 15A to FIG. 15D, FIG. 16E, and FIG. 16F each illustrate a cross-sectional view along the dashed-dotted line X1-X2 and a cross-sectional view along the dashed-dotted line Y1-Y2 in FIG. 1A side by side.

Thin films included in the display apparatus (e.g., insulating films, semiconductor films, and conductive films) can be formed by a sputtering method, a CVD method, a vacuum evaporation method, a pulsed laser deposition (PLD) method, an ALD method, or the like. Examples of the CVD method include a PECVD method and a thermal CVD method. An example of the thermal CVD method is a metal organic chemical vapor deposition (MOCVD) method.

The thin films included in the display apparatus (e.g., insulating films, semiconductor films, and conductive films) can be formed by a wet process such as spin coating, dipping, spray coating, ink-jetting, dispensing, screen printing, offset printing, doctor blade coating, slit coating, roll coating, curtain coating, or knife coating.

Specifically, to manufacture of the light-emitting device, a vacuum process such as an evaporation method and a solution process such as a spin coating method or an ink-jet method can be used. Examples of the evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an ink-jet method, a screen printing (stencil) method, an offset printing (planography) method, a flexography (relief printing) method, a gravure printing method, or a micro-contact printing method).

Thin films included in the display apparatus can be processed by photolithography or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography. In one of the methods, a resist mask is formed over a thin film to be processed, the thin film is processed by etching or the like, and then the resist mask is removed. In the other method, a photosensitive thin film is formed and then processed into a desired shape by light exposure and development.

As light used for light exposure in photolithography, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. Light exposure may be performed by liquid immersion exposure technique. As the light used for light exposure, extreme ultraviolet (EUV) light or X-rays may be used. Instead of the light used for light exposure, an electron beam can also be used. Extreme ultraviolet light, X-rays, or an electron beam is preferably used, in which case extremely minute processing can be performed. Note that a photomask is not needed when light exposure is performed by scanning with a beam such as an electron beam.

For etching of the thin films, dry etching, wet etching, a sandblasting method, or the like can be used.

First, the insulating layer 255a, the insulating layer 255b, and the insulating layer 255c are formed in this order over the layer 101. Then, the pixel electrode 111R, the pixel electrode 111G, the pixel electrode 111B, and the conductive layer 123 are formed over the insulating layer 255c (FIG. 14A).

First, a conductive film to be the pixel electrodes is formed over the insulating layer 255c, a resist mask is formed over the conductive film by photolithography, and an unnecessary portion of the conductive film is removed by etching. After that, the resist mask is removed to form the pixel electrode 111R, the pixel electrode 111G, the pixel electrode 111B, and the conductive layer 123. The conductive film to be the pixel electrodes can be formed by a sputtering method or a vacuum evaporation method, for example. The conductive film can be processed by wet etching or dry etching. The conductive film is preferably processed by anisotropic etching.

In processing of the conductive film, a depressed portion is preferably formed in the insulating layer 255c by processing the insulating layer 255c. This can increase the height of the sidewall insulating layer 114 to be formed later. Accordingly, local thinning of the EL layer 113 to be formed later or split of the EL layer 113 for light-emitting devices can be facilitated. Note that other examples of the structure of one embodiment of the present invention include a structure in which an opening is provided in the insulating layer 255c and a depressed portion is provided in the insulating layer 255b and a structure in which an opening is provided in the insulating layer 255b and the insulating layer 255c and a depressed portion is provided in the insulating layer 255a. In the case where the pixel electrode is sufficiently thick, for example, the depressed portion and the opening are not necessarily provided in the insulating layer 255c.

In other words, the thickness of the insulating layer 255c in a region not overlapping with any of the pixel electrode 111R, the pixel electrode 111G, the pixel electrode 111B, and the conductive layer 123 is preferably smaller than the thickness of the insulating layer 255c in a region overlapping with the pixel electrode 111R, the pixel electrode 111G, and the pixel electrode 111B or the conductive layer 123.

Next, an insulating film 114A is formed over the insulating layer 255c, the pixel electrode 111R, the pixel electrode 111G, the pixel electrode 111B, and the conductive layer 123 (FIG. 14B).

The insulating film 114A is a film to be the sidewall insulating layer 114 by processing later. Thus, the insulating film 114A can have the structure that is described in Embodiment 1 and is applicable to the sidewall insulating layer 114.

Next, the sidewall insulating layer 114 is formed by processing the insulating film 114A (FIG. 14C). By processing the insulating film 114A, the top surfaces of the insulating layer 255c, the pixel electrode 111R, the pixel electrode 111G, the pixel electrode 111B, and the conductive layer 123 are exposed. The sidewall insulating layer 114 is provided in contact with the side surfaces of the pixel electrode 111R, the pixel electrode 111G, the pixel electrode 111B, and the conductive layer 123.

The sidewall insulating layer 114 can be formed by performing etching substantially uniformly on the top surface of the insulating film 114A, for example. Such uniform etching for planarization is also referred to as etch-back processing. Note that the sidewall insulating layer 114 can also be formed by photolithography.

The insulating film 114A can be processed by wet etching or dry etching and is preferably processed by dry etching. The insulating film 114A is preferably processed by anisotropic etching.

Note that in processing of the insulating film 114A, the insulating layer 255c may also be processed to form a depressed portion in the insulating layer 255c. The depressed portion formed in the insulating layer 255c facilitates local thinning of the EL layer 113 to be formed later or split of the EL layer 113 for light-emitting devices. Note that examples of the structure of one embodiment of the present invention include a structure in which an opening is provided in the insulating layer 255c and a depressed portion is provided in the insulating layer 255b and a structure in which an opening is provided in the insulating layer 255b and the insulating layer 255c and a depressed portion is provided in the insulating layer 255a. In the case where the pixel electrode is sufficiently thick, for example, the depressed portion and the opening are not necessarily provided in the insulating layer 255c.

In other words, in FIG. 14C, the thickness of the insulating layer 255c in an exposed region (a region not overlapping with any of the sidewall insulating layer 114, the pixel electrode 111R, the pixel electrode 111G, the pixel electrode 111B, and the conductive layer 123) may be smaller than the thickness of the insulating layer 255c in a region overlapping with the sidewall insulating layer 114 (see FIG. 3D).

An end portion of the sidewall insulating layer 114 can have a rounded shape. For example, the end portion of the sidewall insulating layer 114 is rounded as illustrated in FIG. 14C, FIG. 1B, FIG. 3A to FIG. 3D, and the like in the case where an upper portion of the insulating film 114A is etched by anisotropic etching in formation of the sidewall insulating layer 114 by dry etching. The end portion of the sidewall insulating layer 114 is preferably rounded, in which case coverage with a film to be formed later can be improved.

Next, the EL layer 113 is formed over the pixel electrode 111R, the pixel electrode 111G, and the pixel electrode 111B (FIG. 14D). The EL layer 113 contains a light-emitting material emitting blue light and a light-emitting material emitting light having a longer wavelength than blue light. FIG. 14D illustrates an example in which the island-shaped EL layer 113 is provided for each light-emitting device. That is, the island-shaped EL layer 113 is provided over each of the pixel electrode 111R, the pixel electrode 111G, and the pixel electrode 111B.

In a region between the pixel electrode 111R and the pixel electrode 111G, the material layer 113s is provided over the insulating layer 255c. Similarly, the material layer 113s is provided over the insulating layer 255c also in a region between the pixel electrode 111G and the pixel electrode 111B and a region between the pixel electrode 111B and the pixel electrode 111R. The material layer 113s is formed in the same step as the EL layer 113 and has the same structure as the EL layer 113.

As illustrated in FIG. 14D, the EL layer 113 is not formed over the conductive layer 123 in the cross-sectional view along the dashed-dotted line Y1-Y2. The EL layer 113 can be formed only in a desired region by using an area mask, for example.

The EL layer 113 can be formed by an evaporation method, specifically a vacuum evaporation method, for example. The EL layer 113 may be formed by a transfer method, a printing method, an ink-jet method, a coating method, or the like.

Next, an insulating film 125A to be the insulating layer 125 later is formed to cover the EL layer 113, the sidewall insulating layer 114, and the material layer 113s (FIG. 14E).

As described later, an insulating film 127a is formed in contact with the top surface of the insulating film 125A. Thus, the top surface of the insulating film 125A preferably has high adhesion to a resin composite (e.g., a photosensitive resin composite containing an acrylic resin) that is used for the insulating film 127a. To improve the adhesion, the top surface of the insulating film 125A is preferably made hydrophobic (or more hydrophobic) by surface treatment. For example, the treatment is preferably performed using a silylating agent such as hexamethyldisilazane (HMDS). By making the top surface of the insulating film 125A hydrophobic in this manner, the insulating film 127a can be formed with high adhesion.

Then, an insulating film 127a is formed over the insulating film 125A (FIG. 15A).

The insulating film 125A and the insulating film 127a are preferably formed by a formation method that causes less damage to the EL layer 113. In particular, the insulating film 125A, which is formed in contact with the top surface of the EL layer 113, is preferably formed by a formation method that causes less damage to the EL layer 113 than the formation method of the insulating film 127a.

The insulating film 125A and the insulating film 127a are each formed at a temperature lower than the upper temperature limit of the EL layer 113. When the insulating film 125A is formed at a high substrate temperature, the formed film, even with a small thickness, can have a low impurity concentration and a high barrier property against at least one of water and oxygen.

The insulating film 125A and the insulating film 127a are preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As described above, a material with high heat resistance is used for the light-emitting device of the display apparatus of one embodiment of the present invention. Thus, the substrate temperature in formation of the insulating film 125A and the insulating film 127a can be higher than or equal to 100° C., higher than or equal to 120° C., or higher than or equal to 140° C. For example, an inorganic insulating film formed at a higher temperature can be denser and have a higher barrier property. Therefore, forming the insulating film 125A at such a temperature can further reduce damage to the EL layer 113 in the formation and improve the reliability of the light-emitting device.

As the insulating film 125A, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125A is preferably formed by an ALD method, for example. An ALD method is preferably used, in which case damage due to the film formation can be reduced and a film with high coverage can be formed. As the insulating film 125A, an aluminum oxide film is preferably formed by an ALD method, for example.

Alternatively, the insulating film 125A may be formed by a sputtering method, a CVD method, or a PECVD method that has a higher deposition rate than an ALD method. In that case, a highly reliable display apparatus can be manufactured with high productivity.

The insulating film 127a is preferably formed by the above-described wet process. For example, the insulating film 127a is preferably formed by spin coating using a photosensitive resin, specifically, a photosensitive resin composition containing an acrylic resin.

Heat treatment (also referred to as pre-baking) is preferably performed after the insulating film 127a is formed. The heat treatment is performed at a temperature lower than the upper temperature limit of the EL layer 113. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the insulating film 127a can be removed.

Next, part of the insulating film 127a is exposed to light by irradiation with visible light or ultraviolet rays (FIG. 15B). In the case where a positive photosensitive resin composition containing an acrylic resin is used for the insulating film 127a, a region where the insulating layer 127 is not formed in a later step is irradiated with visible light or ultraviolet rays using a mask 136. The insulating layer 127 is formed in regions interposed between two adjacent pixel electrodes among the pixel electrode 111R, the pixel electrode 111G, and the pixel electrode 111B, and a region surrounding the conductive layer 123. Thus, as illustrated in FIG. 15B, in the insulating film 127a, a portion overlapping with the pixel electrode 111R, a portion overlapping with the pixel electrode 111G, a portion overlapping the pixel electrode 111B, and a portion overlapping with the conductive layer 123 are irradiated with light 139.

Note that the width of the insulating layer 127 to be formed later can be controlled by the region exposed to light here. In this embodiment, processing is performed such that the insulating layer 127 includes a portion overlapping with the top surface of the pixel electrode (FIG. 4A). As illustrated in FIG. 7A or FIG. 7B, the insulating layer 127 does not necessarily include a portion overlapping with the top surface of the pixel electrode.

Light used for the light exposure preferably includes the i-line (wavelength: 365 nm). Light used for the light exposure may include at least one of the g-line (wavelength: 436 nm) and the h-line (wavelength: 405 nm).

Although FIG. 15B illustrates an example in which a positive photosensitive resin is used for the insulating film 127a and a region where the insulating layer 127 is not formed is irradiated with visible light or ultraviolet rays, the present invention is not limited thereto. For example, a negative photosensitive resin may be used for the insulating film 127a. In that case, a region where the insulating layer 127 is formed is irradiated with visible light or ultraviolet rays with a different mask.

Next, as illustrated in FIG. 15C, the region of the insulating film 127a exposed to light is removed by development, so that an insulating layer 127b is formed. The insulating layer 127b is formed in regions interposed between two adjacent pixel electrodes among the pixel electrode 111R, the pixel electrode 111G, and the pixel electrode 111B, and a region surrounding the conductive layer 123. In the case where an acrylic resin is used for the insulating film 127a, an alkaline solution is preferably used as a developer, and for example, an aqueous solution of tetramethyl ammonium hydroxide (TMAH) can be used.

Note that a step of removing a development residue (what is called a scum) may be performed after the development. For example, the residue can be removed by ashing using oxygen plasma. The step of removing a residue may be performed after each development step described below.

Etching may be performed to adjust the surface level of the insulating layer 127b. Etching may be performed to adjust the surface level of the insulating layer 127b.

Note that after the development and before post-baking, light exposure may be performed so that the insulating layer 127b is irradiated with visible light or ultraviolet rays. The energy density of the light exposure is preferably greater than 0 mJ/cm² and less than or equal to 800 mJ/cm², further preferably greater than 0 mJ/cm² and less than or equal to 500 mJ/cm². Performing such light exposure after the development can improve the transparency of the insulating layer 127b in some cases. In addition, the insulating layer 127b can be changed into a tapered shape at low temperature in some cases.

By contrast, when light exposure is not performed on the insulating layer 127b, the shape of the insulating layer 127b can be easily changed or the insulating layer 127 can be easily changed into a tapered shape in a later step in some cases. Thus, in some cases, it is preferable not to perform light exposure on the insulating layer 127b after the development.

Next, heat treatment (also referred to as post-baking) is performed after the insulating layer 127b is formed. As illustrated in FIG. 15D, the heat treatment can change the insulating layer 127b into the insulating layer 127 with a tapered side surface. The heat treatment is performed at a temperature lower than the upper temperature limit of the EL layer 113. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced pressure atmosphere. The heat treatment is preferably performed in a reduced-pressure atmosphere, in which case drying can be performed at a lower temperature. The heat treatment in this step is preferably performed at a higher substrate temperature than the heat treatment (pre-baking) after formation of the insulating film 127a. In that case, adhesion between the insulating layer 127 and the insulating layer 125 and the corrosion resistance of the insulating layer 127 can be improved.

As illustrated in FIG. 6A and FIG. 6B, the side surface of the insulating layer 127 might have a concave shape depending on the materials for the insulating layer 127, or the temperature, time, and atmosphere of the post-baking. For example, the insulating layer 127 is more likely to be changed in shape to have a concave shape in a cross-sectional view as the post-baking is performed at higher temperature or for a longer time. In addition, as described above, in the case where light exposure is not performed on the insulating layer 127b after the development, the shape of the insulating layer 127 is likely to change at the time of the post-baking in some cases.

Next, as illustrated in FIG. 15D, etching treatment is performed using the insulating layer 127 as a mask to remove part of the insulating film 125A. Consequently, openings are formed in the insulating film 125A (i.e., the insulating layer 125 is formed), and the top surfaces of the EL layers 113 and the conductive layer 123 are exposed.

The etching treatment can be performed by dry etching or wet etching.

In the case where dry etching is employed, a chlorine-based gas is preferably used. As the chlorine-based gas, Cl₂, BCl₃, SiCl₄, CCl₄, or the like can be used alone or two or more of the gases can be mixed and used. Moreover, an oxygen gas, a hydrogen gas, a helium gas, an argon gas, or the like or a mixture of two or more of the gases can be added to the chlorine-based gas as appropriate. By employing dry etching, the thin regions of the insulating layer 125 can be formed with a favorable in-plane uniformity.

In the case where dry etching is employed, a by-product or the like generated by the dry etching is sometimes deposited on the top surface and the side surface of the insulating layer 127, for example. Thus, a component contained in the etching gas, a component contained in the insulating film 125A, or the like might be contained in the insulating layer 127 after the display apparatus is completed.

Furthermore, the etching treatment is preferably performed by wet etching. Employing wet etching can reduce damage to the EL layer 113 as compared with the case of employing dry etching. For example, the wet etching can be performed using an alkaline solution or the like. For example, wet etching of an aluminum oxide film is preferably performed using an aqueous solution of tetramethyl ammonium hydroxide (TMAH) that is an alkaline solution. In that case, the wet etching can be performed by a puddle method.

As described above, by providing the insulating layer 125 and the insulating layer 127, a connection defect due to a split portion and an increase in electric resistance due to a locally thinned portion can be inhibited from being caused in the common electrode 115 between the light-emitting devices. Consequently, the display apparatus of one embodiment of the present invention can have improved display quality. Moreover, the manufacturing yield of the light-emitting devices can be further increased.

Heat treatment may be performed after part of the EL layer 113 is exposed. The heat treatment can remove water contained in the EL layer 113, water adsorbed onto the surface of the EL layer 113, and the like. The shape of the insulating layer 127 may be changed by the heat treatment. Specifically, the insulating layer 127 may be extended to cover at least one of the end portion of the insulating layer 125 and the top surface of the EL layer 113. For example, the insulating layer 127 may have a shape illustrated in FIG. 5A and FIG. 5B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case dehydration can be performed at a lower temperature. Note that the temperature range of the heat treatment is preferably set as appropriate in consideration of the upper temperature limit of the EL layer 113. In consideration of the upper temperature limit of the EL layer 113, a temperature higher than or equal to 70° C. and lower than or equal to 120° C. is particularly preferable in the above temperature ranges.

If the insulating layer 125 is etched at a time after the post-baking, the insulating layer 125 under the end portion of the insulating layer 127 may be eliminated by side etching and a cavity may be formed. The cavity causes unevenness on the formation surface of the common electrode 115; hence disconnection of the common electrode 115 is more likely to be caused. For this reason, the etching treatment for the insulating layer 125 is preferably performed separately before and after the post-baking.

A method for performing etching treatment for the insulating layer 125 separately before and after the post-baking will be described below with reference to FIGS. 16A to 16D.

FIG. 16A is an enlarged view of the end portions of the EL layer 113 and the insulating layer 127b and the vicinity thereof illustrated in FIG. 15C. In other words, FIG. 16A illustrates the insulating layer 127b formed by the development.

Next, as illustrated in FIG. 16B, etching treatment is performed using the insulating layer 127b as a mask to remove part of the insulating film 125A, so that the insulating film 125A is partly thinned. Accordingly, an insulating layer 125B is formed under the insulating layer 127b. Note that the etching treatment using the insulating layer 127b as a mask is may be hereinafter referred to as first etching treatment.

The first etching treatment can be performed by dry etching or wet etching.

As illustrated in FIG. 16B, etching is performed using the insulating layer 127b having a tapered side surface as a mask, whereby the insulating layer 125B whose top surface is partly tapered can be formed relatively easily.

As illustrated in FIG. 16B, in the first etching treatment, a thin portion of the insulating layer 125B (a portion not overlapping with the insulating layer 127b) is not completely removed and the etching treatment is stopped in this state. The insulating layer 125B is made to remain over the EL layer 113 in this manner, whereby the EL layer 113 can be prevented from being damaged by treatment in a later step.

Note that although FIG. 16B illustrates an example in which the shape of the insulating layer 127b is not changed from that in FIG. 16A, the present invention is not limited thereto. For example, the end portion of the insulating layer 127b droops to be in contact with the top surface of the insulating layer 125B in some cases. As described above, in the case where light exposure is not performed on the insulating layer 127b after the development, the shape of the insulating layer 127b is likely to change in some cases.

Next, post-baking is performed. As illustrated in FIG. 16C, the post-baking can change the insulating layer 127b into the insulating layer 127 with a tapered side surface. As described above, in some cases, the insulating layer 127b is already changed in shape and has a tapered side surface at the time when the first etching treatment is finished.

In the first etching treatment, the thin portion of the insulating layer 125B is not completely removed and the insulating layer 125B in this state is made to remain, whereby the EL layer 113 can be prevented from being damaged and deteriorating by the post-baking. Thus, the reliability of the light-emitting devices can be improved.

Next, as illustrated in FIG. 16D, etching treatment is performed using the insulating layer 127 as a mask to remove the part of the insulating layer 125B (the thin portion). Consequently, openings are formed in the insulating layer 125B (i.e., the insulating layer 125 is formed), and the top surfaces of the EL layers 113 and the conductive layer 123 are exposed. Note that the etching treatment using the insulating layer 127 as a mask is may be hereinafter referred to as second etching treatment.

FIG. 16D illustrates an example in which part of the end portion of the insulating layer 125 (specifically, the portion having a tapered shape formed by the first etching treatment) is covered with the insulating layer 127 and the portion having a tapered shape formed by the second etching treatment is exposed. That is, this structure corresponds to the structure illustrated in FIG. 4A and FIG. 4B.

As described above, when etching is performed before and after the post-baking, the insulating film 125A is side-etched (i.e., the insulating layer 125B is formed) by the first etching treatment and accordingly a cavity is formed under the end portion of the insulating layer 127b in some cases. However, the post-baking performed after that can change the insulating layer 127b into the insulating layer 127 with a tapered side surface. Accordingly, the insulating layer 127 can fill the above-described cavity. Since the second etching treatment performed after that etches only the thin portion of the insulating layer 125B (i.e., the portion not overlapping with the insulating layer 127), the amount of side etching is small; thus, a cavity is less likely to be formed or can be extremely small even when formed. Therefore, the formation surface of the common electrode 115 can be flatter.

Note that although the example in which the etching treatment is performed on the insulating film 125A in two separate steps to form the insulating layer 125 is described above, one embodiment of the present invention is not limited thereto. Depending on the thickness of the insulating film 125A, the conditions of the etching treatment, or the like, the etching treatment may be performed on the insulating film 125A only once to form the insulating layer 125.

Note that as illustrated in FIG. 5A, FIG. 6B, and FIG. 7B, the insulating layer 127 may cover the entire end portion of the insulating layer 125. For example, the end portion of the insulating layer 127 droops to cover the end portion of the insulating layer 125 in some cases. Alternatively, for example, the end portion of the insulating layer 127 is in contact with the top surface of the EL layer 113 in some cases. As described above, in the case where light exposure is not performed on the insulating layer 127b after the development, the shape of the insulating layer 127 is likely to change in some cases.

The second etching treatment is preferably performed by wet etching. Employing wet etching can reduce damage to the EL layer 113 as compared with the case of employing dry etching. The wet etching can be performed using an alkaline solution or the like.

Next, the common electrode 115 is formed over the EL layers 113, the conductive layer 123, and the insulating layer 127 (FIG. 16E).

The common electrode 115 can be formed by a sputtering method or a vacuum evaporation method, for example. Alternatively, a film formed by an evaporation method and a film formed by a sputtering method may be stacked.

After that, the protective layer 131 is formed over the common electrode 115 (FIG. 16F). In the case where a structure in which coloring layers are provided over the insulating layer 135 as illustrated in FIG. 1B and the like is employed, the insulating layer 135 is formed over the protective layer 131, and the coloring layer 132R, the coloring layer 132G, and the coloring layer 132B are provided over the insulating layer 135. Then, the substrate 120 is attached onto the coloring layer 132R, the coloring layer 132G, and the coloring layer 132B with the resin layer 122, whereby the display apparatus can be manufactured (FIG. 1B). In the case where a structure in which coloring layers are provided on the substrate 120 side as illustrated in FIG. 10 and the like is employed, the coloring layer 132R, the coloring layer 132G, and the coloring layer 132B are provided over the substrate 120 in advance, and the protective layer 131 and the coloring layers formed over the substrate 120 are attached to each other with the resin layer 122, whereby the display apparatus can be manufactured.

Examples of deposition methods of the protective layer 131 and the insulating layer 135 include a vacuum evaporation method, a sputtering method, a CVD method, and an ALD method.

As described above, in the method for manufacturing a display apparatus of this embodiment, the island-shaped EL layers 113 are formed without using a fine metal mask, so that the island-shaped EL layers 113 can be formed to have a uniform thickness. Accordingly, a high-resolution display apparatus or a display apparatus with a high aperture ratio can be obtained. Furthermore, even when the resolution or the aperture ratio is high and the distance between subpixels is extremely short, the EL layers 113 can be inhibited from being in contact with each other in the adjacent subpixels. Accordingly, generation of leakage current between subpixels can be inhibited. This can prevent crosstalk-induced unintended light emission, so that a display apparatus with extremely high contrast can be obtained.

Furthermore, in the method for manufacturing a display apparatus of this embodiment, subpixels of three colors can be separately formed by forming only one type of EL layer. This can reduce the number of manufacturing steps, so that a display apparatus can be manufactured with high yield.

Providing the insulating layer 127 with a tapered end portion between the island-shaped EL layers 113 adjacent to each other can inhibit the common electrode 115 from being disconnected and prevent the common electrode 115 from being locally thinned at the time of forming the common electrode 115. This can inhibit the common electrode 115 from having a connection defect due to the disconnected portion and an increased electric resistance due to the locally thinned portion. Thus, the display apparatus of one embodiment of the present invention can have both high resolution and high display quality.

This embodiment can be combined with any of the other embodiments as appropriate.

### Embodiment 3

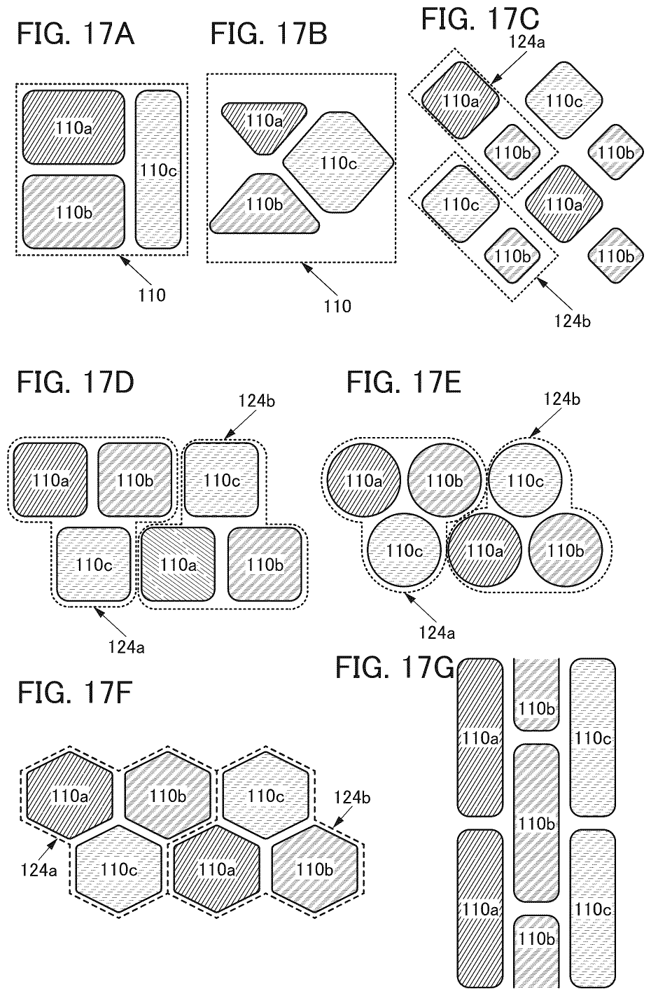

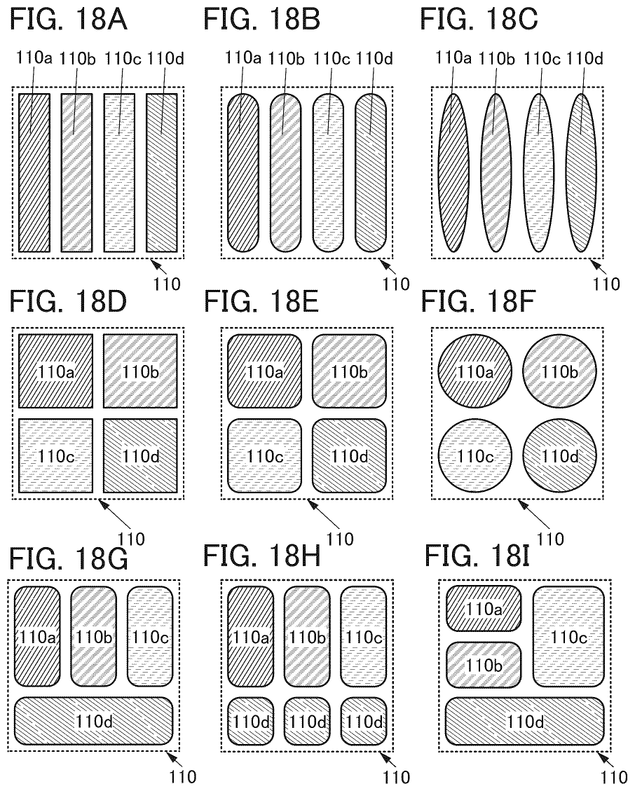

In this embodiment, a display apparatus of one embodiment of the present invention will be described with reference to FIG. 17 and FIG. 18.

### [Pixel Layout]

In this embodiment, pixel layouts different from that in FIG. 1A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region.

Examples of the top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in a diagram, and the components of the circuit may be placed outside the subpixels.

The pixel 110 illustrated in FIG. 17A employs S-stripe arrangement. The pixel 110 illustrated in FIG. 17A is composed of three subpixels: a subpixel 110a, a subpixel 110b, and a subpixel 110c.

The pixel 110 illustrated in FIG. 17B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

A pixel 124a and a pixel 124b illustrated in FIG. 17C employ PenTile arrangement. FIG. 17C illustrates an example in which the pixels 124a each including the subpixel 110a and the subpixel 110b and the pixels 124b each including the subpixel 110b and the subpixel 110c are alternately arranged.

The pixel 124a and the pixel 124b illustrated in FIG. 17D to FIG. 17F employ delta arrangement. The pixel 124a includes two subpixels (the subpixel 110a and the subpixel 110b) in the upper row (first row) and one subpixel (the subpixel 110c) in the lower row (second row). The pixel 124b includes one subpixel (the subpixel 110c) in the upper row (first row) and two subpixels (the subpixel 110a and the subpixel 110b) in the lower row (second row).

FIG. 17D illustrates an example in which each subpixel has a rough tetragonal top surface shape with rounded corners, FIG. 17E illustrates an example in which each subpixel has a circular top surface shape, and FIG. 17F illustrates an example in which each subpixel has a rough hexagonal top surface shape with rounded corners.

In FIG. 17F, subpixels are placed inside the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 110a, the subpixel 110a is surrounded by three subpixels 110b and three subpixels 110c that are alternately arranged.

FIG. 17G illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view.

In the pixels illustrated in FIG. 17A to FIG. 17G, for example, the subpixel 110a is preferably a subpixel R emitting red light, the subpixel 110b is preferably a subpixel G emitting green light, and the subpixel 110c is preferably a subpixel B emitting blue light. Note that the structures of the subpixels are not limited thereto, and the colors and arrangement order of the subpixels can be determined as appropriate. For example, the subpixel 110b may be the subpixel R emitting red light and the subpixel 110a may be the subpixel G emitting green light.

In photolithography, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a pixel electrode may have a polygonal shape with rounded corners, an elliptical shape, a circular shape, or the like. In the display apparatus of one embodiment of the present invention, the top surface shape of the EL layer and the top surface shape of the light-emitting device are affected by the top surface shape of the pixel electrode to be a polygonal shape with rounded corners, an elliptical shape, a circular shape, or the like in some cases.

Note that to obtain a desired top surface shape of the pixel electrode, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 18A to FIG. 18I, the pixel can include four types of subpixels.

The pixels 110 illustrated in FIG. 18A to FIG. 18C employ stripe arrangement.

FIG. 18A illustrates an example in which each subpixel has a rectangular top surface shape, FIG. 18B illustrates an example in which each subpixel has a top surface shape formed by combining two half circles and a rectangle, and FIG. 18C illustrates an example in which each subpixel has an elliptical top surface shape.

The pixels 110 illustrated in FIG. 18D to FIG. 18F employ matrix arrangement.

FIG. 18D illustrates an example in which each subpixel has a square top surface shape, FIG. 18E illustrates an example in which each subpixel has a substantially square top surface shape with rounded corners, and FIG. 18F illustrates an example in which each subpixel has a circular top surface shape.

FIG. 18G and FIG. 18H each illustrate an example in which one pixel 110 is composed of two rows and three columns.

The pixel 110 illustrated in FIG. 18G includes three subpixels (the subpixel 110a, the subpixel 110b, and the subpixel 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 18H includes three subpixels (the subpixel 110a, the subpixel 110b, and the subpixel 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Aligning the positions of the subpixels in the upper row and the lower row as illustrated in FIG. 18H enables efficient removal of dust and the like that would be produced in the manufacturing process. Thus, a display apparatus with high display quality can be provided.

FIG. 18I illustrates an example in which one pixel 110 is composed of three rows and two columns.

The pixel 110 illustrated in FIG. 18I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixel 110a and the subpixel 110b in the left column (first column), the subpixel 110c in the right column (second column), and the subpixel 110d across these two columns.

The pixels 110 illustrated in FIG. 18A to FIG. 18I are each composed of four subpixels: the subpixel 110a, the subpixel 110b, the subpixel 110c, and the subpixel 110d.

The subpixel 110a, the subpixel 110b, the subpixel 110c, and the subpixel 110d can include light-emitting devices that emit light of different colors. The subpixel 110a, the subpixel 110b, the subpixel 110c, and the subpixel 110d can be subpixels of four colors of R, G, B, and white (W), subpixels of four colors of R, G, B, and Y, or subpixels of four colors of R, G, B, and infrared light (IR), for example.

In the pixels 110 illustrated in FIG. 18A to FIG. 18I, the subpixel 110a is preferably a subpixel R emitting red light, the subpixel 110b is preferably a subpixel G emitting green light, the subpixel 110c is preferably a subpixel B emitting blue light, and the subpixel 110d is preferably any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 18G and FIG. 18H, leading to higher display quality. In addition, what is called S-stripe arrangement is employed as the layout of R, G, and B in the pixel 110 illustrated in FIG. 18I, leading to higher display quality.

As described above, the pixel composed of the subpixels each including the light-emitting device can employ any of a variety of layouts in the display apparatus of one embodiment of the present invention.

This embodiment can be combined with any of the other embodiments as appropriate.

### Embodiment 4

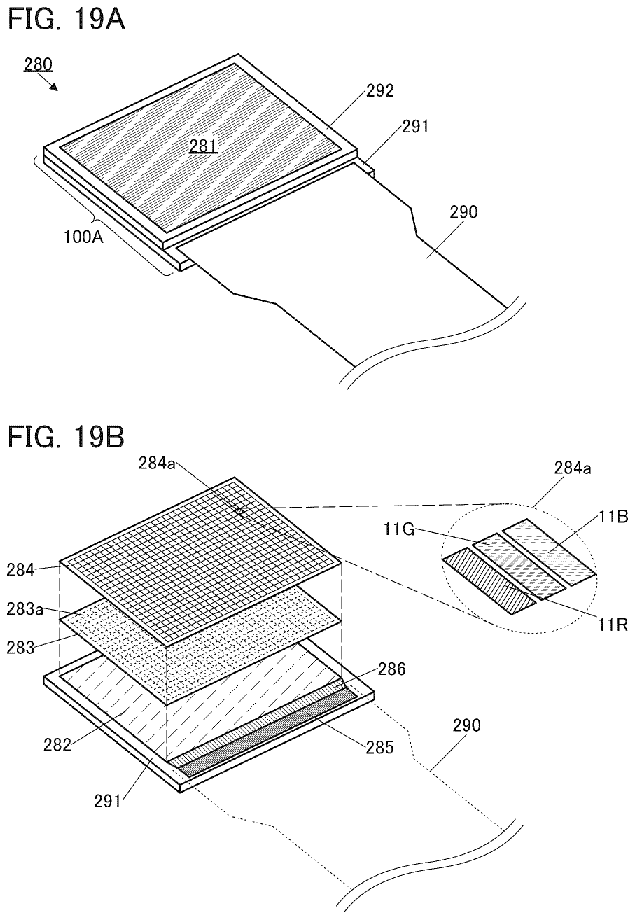

In this embodiment, display apparatuses of one embodiment of the present invention will be described with reference to FIG. 19 to FIG. 28.

The display apparatus in this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus in this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Module]

FIG. 19A is a perspective view of a display module 280. The display module 280 includes a display apparatus 100A and an FPC 290. Note that the display apparatus included in the display module 280 is not limited to the display apparatus 100A and may be any of display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 19B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 19B. The pixel 284a can employ any of the structures described in the above embodiments. FIG. 19B illustrates an example where a structure similar to that of the pixel 110 illustrated in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2,000 ppi, preferably higher than or equal to 3,000 ppi, further preferably higher than or equal to 5,000 ppi, still further preferably higher than or equal to 6,000 ppi, and lower than or equal to 20,000 ppi or lower than or equal to 30,000 ppi.

Such a display module 280 has extremely high resolution, and thus can be suitably used for a VR device such as an HMD or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wristwatch.

### [Display Apparatus 100A]

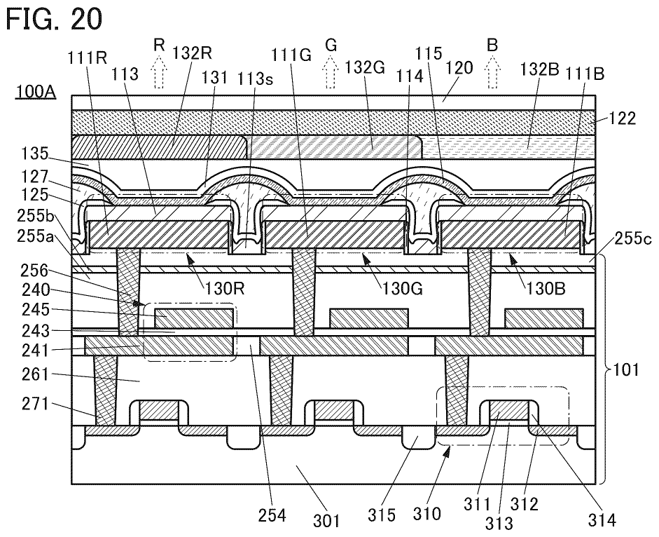

The display apparatus 100A illustrated in FIG. 20 includes a substrate 301, the light-emitting device 130R, the light-emitting device 130G, the light-emitting device 130B, the coloring layer 132R, the coloring layer 132G, the coloring layer 132B, a capacitor 240, and a transistor 310.

The subpixel 11R illustrated in FIG. 19B includes the light-emitting device 130R and the coloring layer 132R, the subpixel 11G includes the light-emitting device 130G and the coloring layer 132G, and the subpixel 11B includes the light-emitting device 130B and the coloring layer 132B. In the subpixel 11R, light emitted from the light-emitting device 130R is extracted as red light (R) to the outside of the display apparatus 100A through the coloring layer 132R. Similarly, in the subpixel 11G, light emitted from the light-emitting device 130G is extracted as green light (G) to the outside of the display apparatus 100A through the coloring layer 132G. In the subpixel 11B, light emitted from the light-emitting device 130B is extracted as blue light (B) to the outside of the display apparatus 100A through the coloring layer 132B.

The substrate 301 corresponds to the substrate 291 illustrated in FIG. 19A and FIG. 19B. A stacked-layer structure including the substrate 301 and the components thereover up to the insulating layer 255c corresponds to the layer 101 in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311 and functions as an insulating layer.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101. The conductive layer can be referred to as a guard ring. By providing the conductive layer, elements such as a transistor and a light-emitting device can be inhibited from being broken by high voltage application due to ESD (electrostatic discharge) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting device 130R, the light-emitting device 130G, and the light-emitting device 130B are provided over the insulating layer 255c. FIG. 20 illustrates an example in which the light-emitting device 130R, the light-emitting device 130G, and the light-emitting device 130B each have the stacked-layer structure illustrated in FIG. 1B.

The pixel electrode 111R, the pixel electrode 111G, and the pixel electrode 111B are each electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. The surface of the insulating layer 255c in contact with the pixel electrode and the surface of the plug 256 in contact with the pixel electrode are level or substantially level with each other. A variety of conductive materials can be used for the plugs.

The protective layer 131 is provided over the light-emitting device 130R, the light-emitting device 130G, and the light-emitting device 130B. The insulating layer 135 is provided over the protective layer 131. Over the insulating layer 135, the coloring layer 132R is provided in a position overlapping with the light-emitting device 130R, the coloring layer 132G is provided in a position overlapping with the light-emitting device 130G, and the coloring layer 132B is provided in a position overlapping with the light-emitting device 130B. The substrate 120 is attached onto the coloring layer 132R, the coloring layer 132G, and the coloring layer 132B with the resin layer 122. Embodiment 1 can be referred to for the details of the light-emitting devices and the components thereover up to the substrate 120. The substrate 120 corresponds to the substrate 292 in FIG. 19A.

### [Display Apparatus 100B]

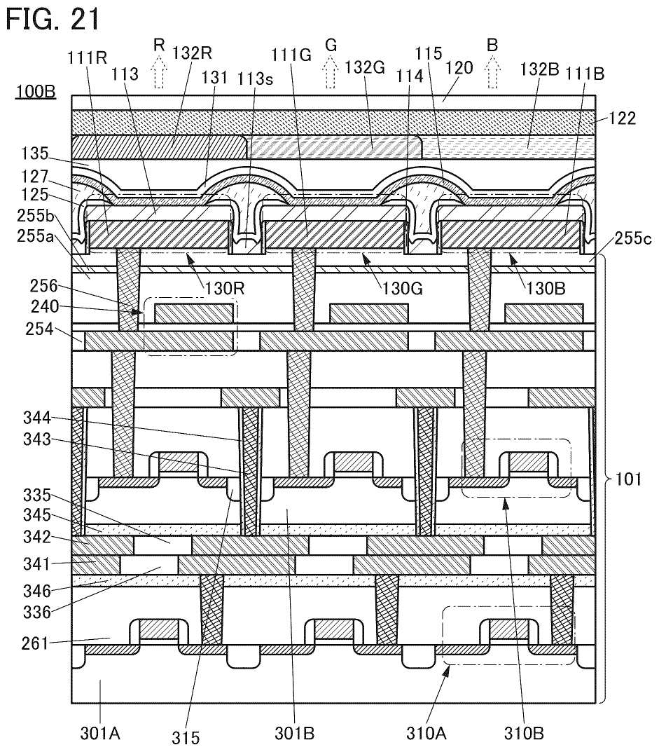

The display apparatus 100B illustrated in FIG. 21 has a structure where a transistor 310A and a transistor 310B in each of which a channel is formed in a semiconductor substrate are stacked. Note that in the following description of display apparatuses, the description of portions similar to those of the above-described display apparatus may be omitted.

In the display apparatus 100B, a substrate 301B provided with the transistor 310B, the capacitor 240, and the light-emitting devices is attached to a substrate 301A provided with the transistor 310A.

Here, an insulating layer 345 is preferably provided on the bottom surface of the substrate 301B (the surface on the substrate 301A side). An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. As the insulating layer 345 and the insulating layer 346, an inorganic insulating film that can be used as the protective layer 131 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities from the plug 343 into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 (the surfaces on the substrate 301A side) are preferably planarized. Here, the conductive layer 342 is electrically connected to the plug 343.

Over the substrate 301A, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-copper) direct bonding (a technique for achieving electrical continuity by connecting Cu (copper) pads).

### [Display Apparatus 100C]

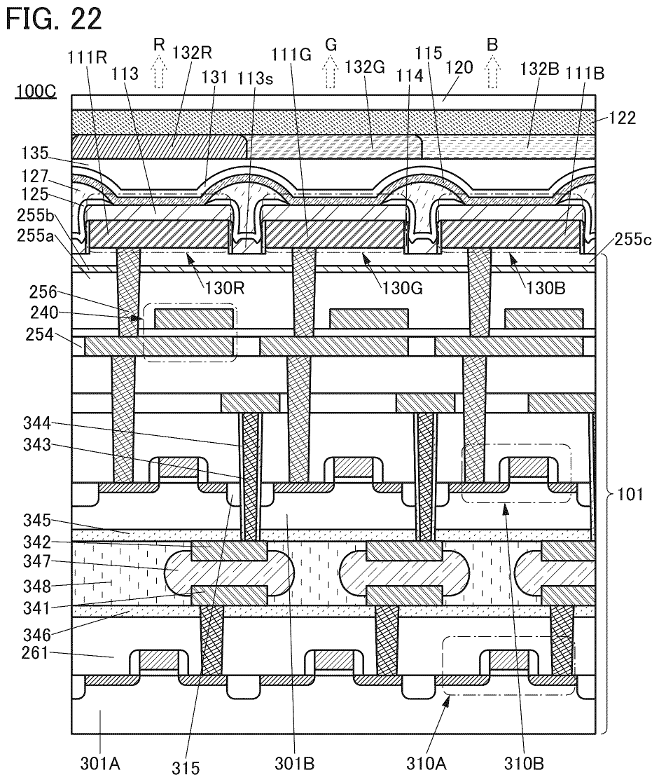

In the display apparatus 100C illustrated in FIG. 22, the conductive layer 341 and conductive layer 342 are bonded to each other with a bump 347.

As illustrated in FIG. 22, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 illustrated in FIG. 21 may be omitted.

### [Display Apparatus 100D]

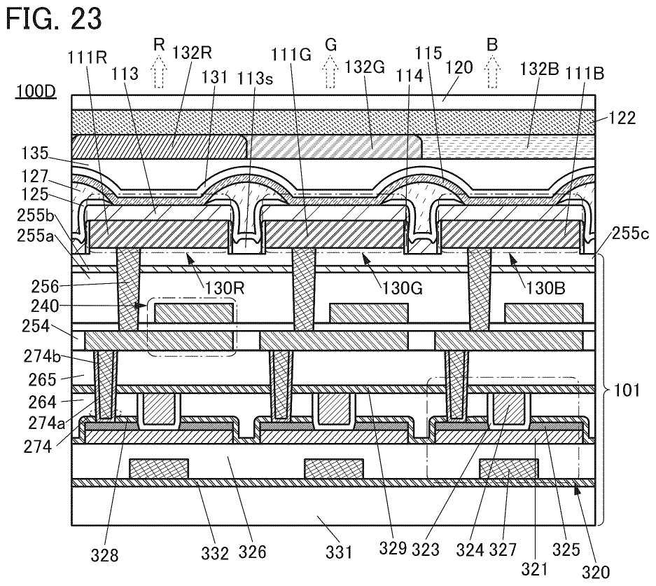

The display apparatus 100D illustrated in FIG. 23 differs from the display apparatus 100A mainly in a structure of a transistor.

A transistor 320 is a transistor that contains a metal oxide (also referred to as an oxide semiconductor) in its semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 19A and FIG. 19B. A stacked-layer structure including the substrate 331 and the components thereover up to the insulating layer 255c corresponds to the layer 101 in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided on and in contact with the semiconductor layer 321 and function as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material through which hydrogen and oxygen are less likely to diffuse is preferably used for the conductive layer 274a.

### [Display Apparatus 100E]

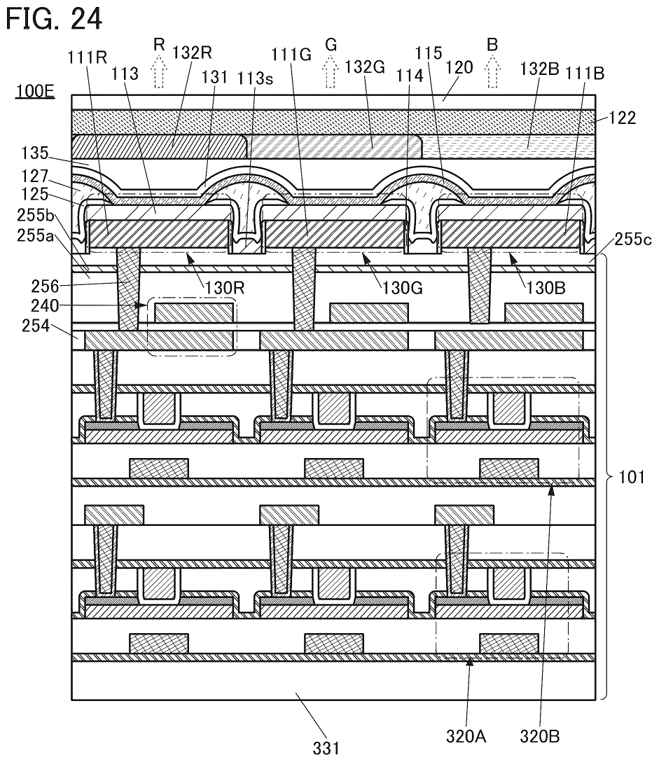

The display apparatus 100E illustrated in FIG. 24 has a structure in which a transistor 320A and a transistor 320B each including an oxide semiconductor in a semiconductor layer where a channel is formed are stacked.

The description of the display apparatus 100D can be referred to for the transistor 320A, the transistor 320B, and the components around them.

Although the structure in which two transistors each including an oxide semiconductor are stacked is described here, one embodiment of the present invention is not limited thereto. For example, three or more transistors may be stacked.

### [Display Apparatus 100F]

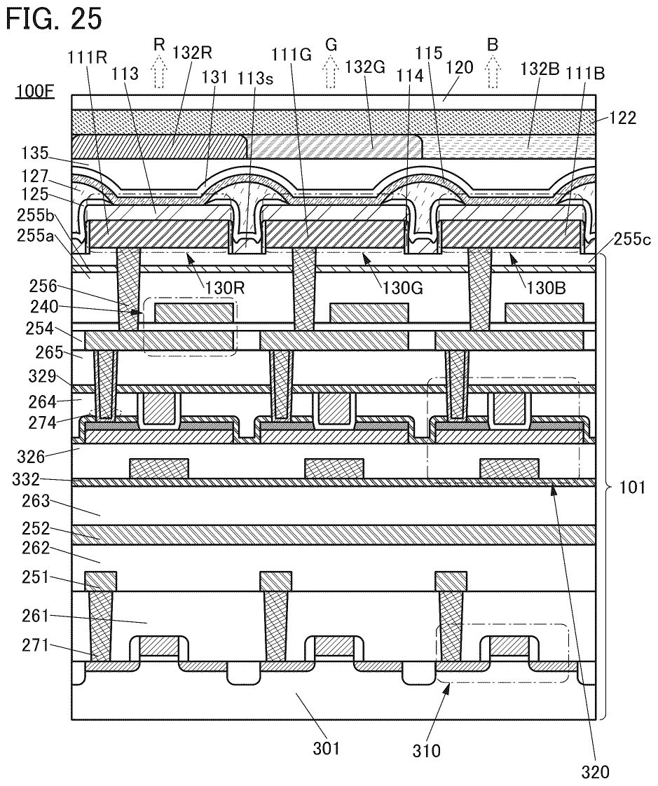

The display apparatus 100F illustrated in FIG. 25 has a structure in which the transistor 310 whose channel is formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display region.

### [Display Apparatus 100G]

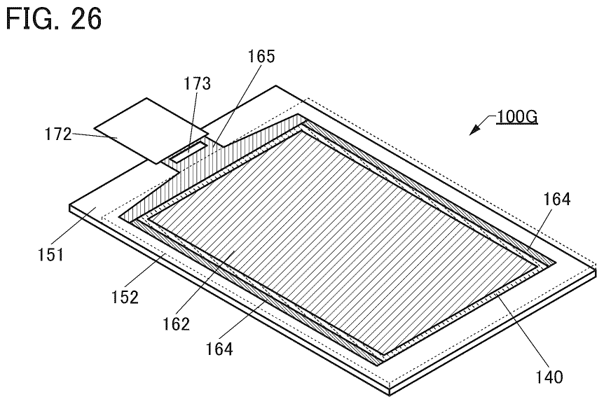

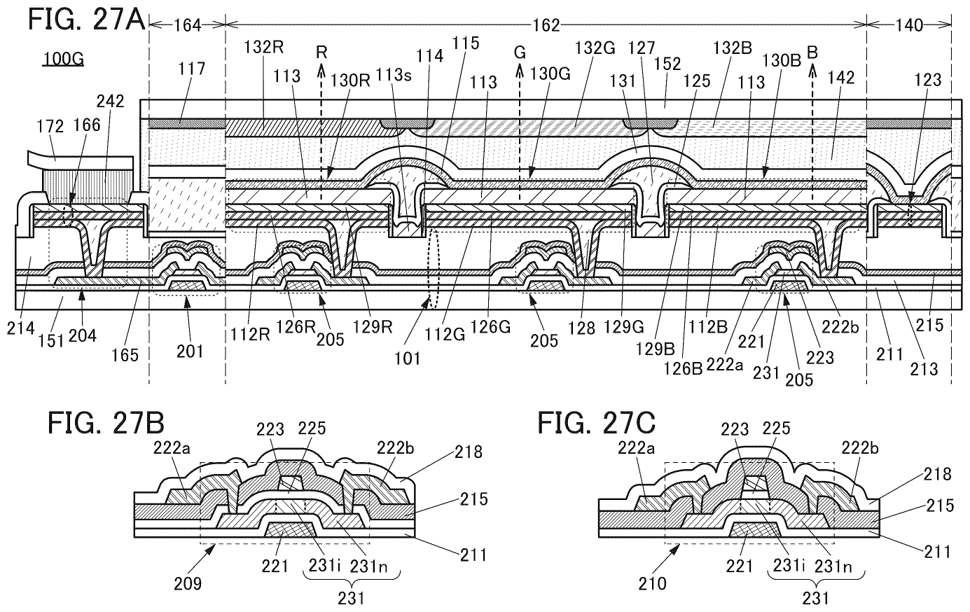

FIG. 26 is a perspective view of a display apparatus 100G, and FIG. 27A is a cross-sectional view of the display apparatus 100G.

In the display apparatus 100G, a substrate 152 and a substrate 151 are attached to each other. In FIG. 26, the substrate 152 is denoted by a dashed line.

The display apparatus 100G includes a display portion 162, the connection portion 140, circuits 164, a wiring 165, and the like. FIG. 26 illustrates an example in which an IC 173 and an FPC 172 are mounted on the display apparatus 100G. Thus, the structure illustrated in FIG. 26 can be regarded as a display module including the display apparatus 100G, the IC (integrated circuit), and the FPC.

The connection portion 140 is provided outside the display portion 162. The connection portion 140 can be provided along one or more sides of the display portion 162. The number of the connection portions 140 may be one or more. FIG. 26 illustrates an example in which the connection portion 140 is provided to surround the four sides of the display portion 162. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 26 illustrates an example where the IC 173 is provided over the substrate 151 by a COG (Chip On Glass) method, a COF (Chip On Film) method, or the like. As the IC 173, an IC including a scan line driver circuit, a signal line driver circuit, or the like can be used, for example. Note that the display apparatus 100G and the display module are not necessarily provided with an IC. The IC may be mounted on the FPC by a COF method or the like.

FIG. 27A illustrates examples of cross sections of part of a region including the FPC 172, part of the circuit 164, part of the display portion 162, part of the connection portion 140, and part of a region including an end portion of the display apparatus 100G.

In the display apparatus 100G illustrated in FIG. 27A, a transistor 201, a transistor 205, the light-emitting device 130R, the light-emitting device 130G, the light-emitting device 130B, the coloring layer 132R transmitting red light, the coloring layer 132G transmitting green light, the coloring layer 132B transmitting blue light, and the like are provided between the substrate 151 and the substrate 152.

The structure of each of the light-emitting device 130R, the light-emitting device 130G, and the light emitting device 130B is similar to the stacked-layer structure illustrated in FIG. 1B except for the structure of the pixel electrode. Embodiment 1 can be referred to for the details of the light-emitting devices.

The light-emitting device 130R includes a conductive layer 112R, a conductive layer 126R over the conductive layer 112R, and a conductive layer 129R over the conductive layer 126R. All of the conductive layer 112R, the conductive layer 126R, and the conductive layer 129R can be referred to as pixel electrodes, or one or two of them can be referred to as pixel electrodes.

The light-emitting device 130G includes a conductive layer 112G, a conductive layer 126G over the conductive layer 112G, and a conductive layer 129G over the conductive layer 126G.

The light-emitting device 130B includes a conductive layer 112B, a conductive layer 126B over the conductive layer 112B, and a conductive layer 129B over the conductive layer 126B.

The conductive layer 112R is connected to the conductive layer 222b included in the transistor 205 through the opening provided in an insulating layer 214. The end portion of the conductive layer 112R, the end portion of the conductive layer 126R, and the end portion of the conductive layer 129R are preferably aligned or substantially aligned with each other. In that case, the height of the sidewall insulating layer 114 can be the same as or larger than the sum of the thicknesses of the three conductive layers, so that the EL layer can be locally thinned or split easily by the sidewall insulating layer 114. For example, a conductive layer functioning as a reflective electrode can be used as the conductive layer 112R and the conductive layer 126R, and a conductive layer functioning as a transparent electrode can be used as the conductive layer 129R.

Since the conductive layer 112G, 126G, and 129G and the conductive layers 112B, 126B, and 129B are similar to the conductive layers 112R, 126R, and 129R, the detailed description thereof is omitted.

Depressed portions are formed on the conductive layer 112R, the conductive layer 112G, and the conductive layer 112B to cover the openings provided in the insulating layer 214. A layer 128 is embedded in the depression portion.

The layer 128 has a function of filling the depressed portions on the conductive layer 112R, the conductive layer 112G, and the conductive layer 112B. The conductive layer 126R, the conductive layer 126G, and the conductive layer 126B that are electrically connected to the conductive layer 112R, the conductive layer 112G, and the conductive layer 112B, respectively, are provided over the conductive layer 112R, the conductive layer 112G, the conductive layer 112B, and the layer 128. Thus, regions overlapping with the depressed portions on the conductive layer 112R, the conductive layer 112G, and the conductive layer 112B can also be used as light-emitting regions, increasing the pixel aperture ratio.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material, particularly preferably formed using an organic insulating material.

As the layer 128, an insulating layer containing an organic material can be suitably used. Examples of an organic material that can be used for the layer 128 include organic materials that can be used for the protective layer 131 or the insulating layer 135.

The side surfaces and parts of the top surfaces of the adjacent EL layers 113, part of the side surface of the sidewall insulating layer 114, the top surface of the material layer 113s, and the side surface and part of the top surface of the conductive layer 123 are covered with the insulating layer 125 and the insulating layer 127. The common electrode 115 is provided over the EL layer 113, the insulating layer 125, and the insulating layer 127 to cover these layers. Thus, disconnection of the common electrode 115 due to a step between adjacent pixel electrodes can be inhibited, and the manufacturing yield of the light-emitting devices can be further increased. The common electrode 115 is one continuous film shared by the plurality of light-emitting devices.

The protective layer 131 is provided over the light-emitting device 130R, the light-emitting device 130G, and the light-emitting device 130B. The protective layer 131 and the substrate 152 are attached to each other with an adhesive layer 142. The substrate 152 is provided with a light-blocking layer 117, the coloring layer 132R, the coloring layer 132G, and the coloring layer 132B. A solid sealing structure, a hollow sealing structure, or the like can be employed to seal the light-emitting devices. In FIG. 27A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. In that case, the adhesive layer 142 may be provided not to overlap with the light-emitting devices. Alternatively, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit 164. It is further preferable that the protective layer 131 be provided to extend to the end portion of the display apparatus 100G. Meanwhile, a connection portion 204 has a portion not provided with the protective layer 131 so that the FPC 172 and a conductive layer 166 are electrically connected to each other.

The connection portion 204 is provided in a region of the substrate 151 not overlapping with the substrate 152. In the connection portion 204, the wiring 165 is electrically connected to the FPC 172 through the conductive layer 166 and a connection layer 242. An example is described in which the conductive layer 166 has a stacked-layer structure of a conductive film obtained by processing the same conductive film as the conductive layer 112R, the conductive layer 112G, and the conductive layer 112B, a conductive film obtained by processing the same conductive film as the conductive layer 126R, the conductive layer 126G, and the conductive layer 126B, and a conductive film obtained by processing the same conductive film as the conductive layer 129R, the conductive layer 129G, and the conductive layer 129B. On the top surface of the connection portion 204, the conductive layer 166 is exposed. Thus, the connection portion 204 and the FPC 172 can be electrically connected to each other through the connection layer 242.

For example, the protective layer 131 is formed over the entire surface of the display apparatus 100G and then a region of the protective layer 131 overlapping with the conductive layer 166 is removed, so that the conductive layer 166 can be exposed.

Furthermore, a stacked-layer structure of at least one organic layer and a conductive layer may be provided over the conductive layer 166, and the protective layer 131 may be provided over the stacked-layer structure. Then, a separation trigger (a portion that can be a trigger of separation) may be formed in the stacked structure using laser or a sharp cutter (e.g., a needle or a utility knife) to selectively remove the stacked structure and the protective layer 131 thereover, so that the conductive layer 166 is exposed. For example, the protective layer 131 can be selectively removed by pressing an adhesive roller against the substrate 151 and then moving the roller relatively while rotating it. Alternatively, an adhesive tape may be attached to the substrate 151 and then removed. Since adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the EL layer 113, for example. The organic layer may be formed concurrently with the EL layer 113 or may be provided separately. The conductive layer can be formed using the same step and the same material as the common electrode 115. An ITO film is preferably formed as the common electrode 115 and the conductive layer, for example. Note that in the case where a stacked-layer structure is used for the common electrode 115, at least one of the layers included in the common electrode 115 is provided as the conductive layer.

The top surface of the conductive layer 166 may be covered with a mask so that the protective layer 131 is not provided over the conductive layer 166. As the mask, a metal mask (area metal mask) or a tape or a film having adhesiveness or attachability may be used. The protective layer 131 is formed while the mask is placed and then the mask is removed, so that the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 214 in the connection portion 140. An example is described in which the conductive layer 123 has a stacked-layer structure of a conductive film obtained by processing the same conductive film as the conductive layer 112R, the conductive layer 112G, and the conductive layer 112B, a conductive film obtained by processing the same conductive film as the conductive layer 126R, the conductive layer 126G, and the conductive layer 126B, and a conductive film obtained by processing the same conductive film as the conductive layer 129R, the conductive layer 129G, and the conductive layer 129B. The side surface of the conductive layer 123 is covered with the sidewall insulating layer 114. The sidewall insulating layer 114 functions as a sidewall of the conductive layer 123. The top surface and side surface of the sidewall insulating layer 114 and the side surface and part of the top surface of the conductive layer 123 are covered with the insulating layer 125 and the insulating layer 127. The common electrode 115 is provided over the conductive layer 123, the insulating layer 125, and the insulating layer 127 to cover these layers. The common electrode 115 is provided in contact with part of the top surface of the conductive layer 123 (a portion not covered with the insulating layer 125 and the insulating layer 127). That is, in the connection portion 140, the conductive layer 123 and the common electrode 115 are electrically connected to each other.

The display apparatus 100G has a top emission structure. Light emitted from the light-emitting devices is emitted toward the substrate 152. For the substrate 152, a material having a high visible-light-transmitting property is preferably used. The pixel electrode contains a material that reflects visible light, and the counter electrode (the common electrode 115) contains a material that transmits visible light.

A stacked-layer structure including the substrate 151 and the components thereover up to the insulating layer 214 corresponds to the layer 101 in Embodiment 1.

The transistor 201 and the transistor 205 are formed over the substrate 151. These transistors can be formed using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and functions as a planarization layer. Note that the number of gate insulating layers and the number of insulating layers covering the transistors are not limited and may each be one or two or more.

A material into which impurities such as water and hydrogen do not easily diffuse is preferably used for at least one of the insulating layers that cover the transistors. This allows the insulating layer to function as a barrier layer. Such a structure can effectively inhibit diffusion of impurities into the transistors from the outside and improve the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. Accordingly, a depressed portion can be inhibited from being formed in the insulating layer 214 at the time of processing the conductive layer 112R, the conductive layer 126R, the conductive layer 129R, or the like. Alternatively, a depressed portion may be formed in the insulating layer 214 at the time of processing the conductive layer 112R, the conductive layer 126R, the conductive layer 129R, or the like.

Each of the transistor 201 and the transistor 205 includes a conductive layer 221 functioning as a gate electrode, the insulating layer 211 functioning as a gate insulating layer, a conductive layer 222a and the conductive layer 222b functioning as a source electrode and a drain electrode, a semiconductor layer 231, the insulating layer 213 functioning as a gate insulating layer, and a conductive layer 223 functioning as a gate electrode. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gate electrodes may be provided above and below the semiconductor layer where a channel is formed.

The transistor 201 and the transistor 205 have a structure in which the semiconductor layer where a channel is formed is provided between two gate electrodes. The two gate electrodes may be connected to each other and supplied with the same signal to drive the transistor. Alternatively, a potential for controlling the threshold voltage may be supplied to one of the two gate electrodes and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

As the oxide semiconductor having crystallinity, a CAAC (C-Axis-Aligned Crystalline)-OS, an nc (nanocrystalline)-OS, and the like can be given.

Alternatively, a transistor containing silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the display apparatus and a reduction in component cost and mounting cost.

The OS transistor has much higher field-effect mobility than a transistor containing amorphous silicon. In addition, the OS transistor has an extremely low leakage current flowing between a source and a drain in an off state (hereinafter also referred to as an off-state current), and charge accumulated in a capacitor that is connected in series to the transistor can be retained for a long period. Furthermore, power consumption of the display apparatus can be reduced with the OS transistor.

To increase the emission luminance of the light-emitting device included in the pixel circuit, the amount of current fed through the light-emitting device needs to be increased. For that purpose, the source-drain voltage of a driving transistor included in the pixel circuit needs to be increased. An OS transistor has higher withstand voltage between a source and a drain than a Si transistor; hence, high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Consequently, the number of gray levels expressed by the pixel circuit can be increased.

Regarding saturation characteristics of current flowing when transistors operate in a saturation region, even in the case where the source-drain voltage of an OS transistor increases gradually, more stable current (saturation current) can be fed through the OS transistor than through a Si transistor. Thus, by using an OS transistor as the driving transistor, stable current can be fed through light-emitting devices even when the current-voltage characteristics of the EL devices vary, for example. In other words, when the OS transistor operates in the saturation region, the source-drain current hardly changes with an increase in the source-drain voltage; hence, the luminance of the light-emitting device can be stable.

As described above, by using an OS transistor as the driving transistor included in the pixel circuit, it is possible to achieve “inhibition of black-level degradation”, “increase in emission luminance”, “increase in gray level”, “inhibition of variation in light-emitting devices”, and the like.

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin.

It is particularly preferable that an oxide containing indium (In), gallium (Ga), and zinc (Zn) (also referred to as IGZO) be used as the semiconductor layer. Alternatively, it is preferable to use an oxide containing indium, tin, and zinc. Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistors included in the circuit 164 and the transistors included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. A structure where an LTPS transistor and an OS transistor are used in combination is referred to as LTPO in some cases. Note that as a more favorable example, it is preferable to use an OS transistor as, for example, a transistor functioning as a switch for controlling electrical continuity between wirings and an LTPS transistor as, for example, a transistor or the like for controlling current.

For example, one transistor included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device in the pixel circuit can be increased.

Another transistor included in the display portion 162 functions as a switch for controlling selection or non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be significantly reduced. In addition, with the structure, a viewer can notice any one or more of image crispness, image sharpness, a high chroma, and a high contrast ratio in an image displayed on the display apparatus. Note that when the leakage current that might flow through the transistor and the lateral leakage current between the light-emitting devices are extremely low, light leakage that might occur in black display (what is called black-level degradation) or the like can be reduced as much as possible.

FIG. 27B and FIG. 27C illustrate other structure examples of transistors.

A transistor 209 and a transistor 210 each include the conductive layer 221 functioning as a gate electrode, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other pair of low-resistance regions 231n, an insulating layer 225 functioning as a gate insulating layer, the conductive layer 223 functioning as a gate electrode, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 27B illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source electrode, and the other functions as a drain electrode.

Meanwhile, in the transistor 210 illustrated in FIG. 27C, the insulating layer 225 overlaps with the channel formation region 231i of the semiconductor layer 231 and does not overlap with the low-resistance regions 231n. The structure illustrated in FIG. 27C can be formed by processing the insulating layer 225 using the conductive layer 223 as a mask, for example. In FIG. 27C, the insulating layer 215 is provided to cover the insulating layer 225 and the conductive layer 223, and the conductive layer 222a and the conductive layer 222b are connected to the low-resistance regions 231n through the openings in the insulating layer 215.

The light-blocking layer 117 is preferably provided on the surface of the substrate 152 on the substrate 151 side. The light-blocking layer 117 can be provided between adjacent light-emitting devices, in the connection portion 140, and in the circuit 164, for example. A variety of optical members can be placed on the outer surface of the substrate 152.

The material that can be used for the substrate 120 illustrated in FIG. 1B and the like can be used for each of the substrate 151 and the substrate 152.

The material that can be used for the resin layer 122 illustrated in FIG. 1B and the like can be used for the adhesive layer 142.

As the connection layer 242, an anisotropic conductive film (ACF), an anisotropic conductive paste (ACP), or the like can be used.

### [Display Apparatus 100H]

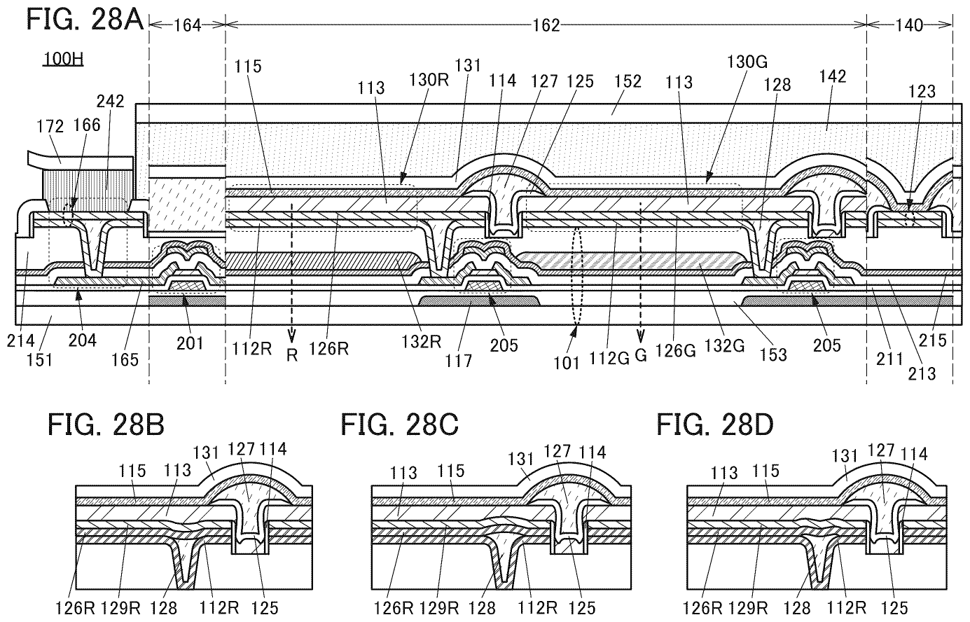

A display apparatus 100H illustrated in FIG. 28A differs from the display apparatus 100G mainly in having a bottom-emission structure.

Light emitted from the light-emitting devices is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor 201 and between the substrate 151 and the transistor 205. FIG. 28A illustrates an example in which the light-blocking layer 117 is provided over the substrate 151, an insulating layer 153 is provided over the light-blocking layer 117, and the transistor 201, the transistor 205, and the like are provided over the insulating layer 153. The coloring layer 132R, the coloring layer 132G, and the coloring layer 132B (not illustrated) are provided over the insulating layer 215.

The light-emitting device 130R includes the conductive layer 112R and the conductive layer 126R over the conductive layer 112R.

The light-emitting device 130G includes the conductive layer 112G and the conductive layer 126G over the conductive layer 112G.

The light-emitting device 130B includes the conductive layer 112B and the conductive layer 126B over the conductive layer 112B (each of which is not illustrated).

A material having a high visible-light-transmitting property is preferably used for each of the conductive layer 112R, the conductive layer 112G, the conductive layer 126R, and the conductive layer 126G. A material reflecting visible light is preferably used for the common electrode 115.

Although FIG. 27A, FIG. 28A, and the like illustrate an example where the top surface of the layer 128 includes a flat portion, the shape of the layer 128 is not particularly limited. FIG. 28B to FIG. 28D illustrate variation examples of the layer 128.

As illustrated in FIG. 28B and FIG. 28D, the top surface of the layer 128 can have a shape such that its center and the vicinity thereof are depressed, i.e., a shape including a concave surface, in a cross-sectional view.

As illustrated in FIG. 28C, the top surface of the layer 128 can have a shape such that its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 112R may be the same or substantially the same, or may be different from each other. For example, the level of the top surface of the layer 128 may be either lower or higher than the level of the top surface of the conductive layer 112R. The same applies to the conductive layer 112G and the conductive layer 112B.

FIG. 28B can be regarded as illustrating an example where the layer 128 fits in the depressed portion of the conductive layer 112R. By contrast, as illustrated in FIG. 28D, the layer 128 may exist also outside the depressed portion of the conductive layer 112R, that is, the layer 128 may be formed to have a top surface wider than the depressed portion. The same applies to the conductive layer 112G and the conductive layer 112B.

This embodiment can be combined with any of the other embodiments as appropriate.

### Embodiment 5

In this embodiment, light-emitting devices that can be used in the display apparatus of one embodiment of the present invention will be described.

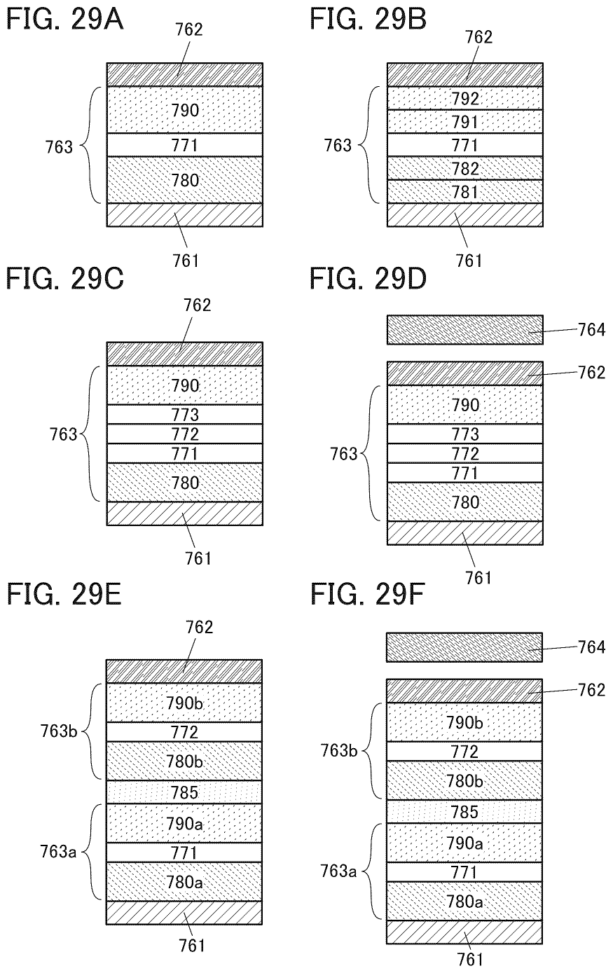

As illustrated in FIG. 29A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). The layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 29A is referred to as a single structure in this specification.

FIG. 29B is a variation example of the EL layer 763 included in the light-emitting device illustrated in FIG. 29A. Specifically, the light-emitting device illustrated in FIG. 29B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 29C and FIG. 29D are variations of the single structure. Although FIG. 29C and FIG. 29D illustrate the examples where three light-emitting layers are included, the light-emitting device having a single structure may include two or four or more light-emitting layers. In addition, the light-emitting device having a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 29E and FIG. 29F is referred to as a tandem structure in this specification. Note that the tandem structure may be referred to as a stack structure. The tandem structure enables a light-emitting device capable of high-luminance light emission. Furthermore, the tandem structure allows the amount of current needed for obtaining the same luminance to be reduced as compared with a single structure, and thus can improve the reliability.

Note that FIG. 29D and FIG. 29F illustrate examples where the display apparatus includes a layer 764 overlapping with the light-emitting device. FIG. 29D illustrates an example where the layer 764 overlaps with the light-emitting device illustrated in FIG. 29C, and FIG. 29F illustrates an example where the layer 764 overlaps with the light-emitting device illustrated in FIG. 29E. In FIG. 29D and FIG. 29F, a conductive film transmitting visible light is used for the upper electrode 762 to extract light to the upper electrode 762 side.

One or both of a color conversion layer and a color filter (coloring layer) can be used as the layer 764.

In FIG. 29C and FIG. 29D, light-emitting substances that emit light of different colors can be used for the light-emitting layer 771, the light-emitting layer 772, and the light-emitting layer 773. In the case where the light-emitting layer 771, the light-emitting layer 772, and the light-emitting layer 773 emit light of complementary colors, white light emission can be obtained from the light-emitting layers as a whole. The light-emitting element having a single structure preferably includes a light-emitting layer containing a light-emitting substance emitting blue light and a light-emitting layer containing a light-emitting substance emitting visible light with a longer wavelength than blue light, for example.

A color filter is preferably provided as the layer 764 illustrated in FIG. 29D. When white light passes through the color filter, light of a desired color can be obtained.

In the case where the light-emitting device having a single structure includes three light-emitting layers, for example, the light-emitting device preferably includes a light-emitting layer containing a light-emitting substance emitting red (R) light, a light-emitting layer containing a light-emitting substance emitting green (G) light, and a light-emitting layer containing a light-emitting substance emitting blue (B) light. The stacking order of the light-emitting layers can be R, G, and B or R, B, and G from the anode side, for example. In that case, a buffer layer may be provided between R and G or between R and B.

For example, in the case where the light-emitting device having a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

The light-emitting device that emits white light preferably contains two or more kinds of light-emitting substances. To obtain white light emission, two or more light-emitting substances are selected such that they emit light of complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

In FIG. 29C and FIG. 29D, the layer 780 and the layer 790 may each independently have a stacked-layer structure of two or more layers as illustrated in FIG. 29B.

In FIG. 29E and FIG. 29F, light-emitting substances that emit light of different colors can be used for the light-emitting layer 771 and the light-emitting layer 772. In the case where the light-emitting layer 771 and the light-emitting layer 772 emit light of complementary colors, white light emission can be obtained from the light-emitting layers as a whole. A color filter is preferably provided as the layer 764 illustrated in FIG. 29F. When white light passes through the color filter, light of a desired color can be obtained.

Although FIG. 29E and FIG. 29F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 29E and FIG. 29F each illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 29E and FIG. 29F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the above structures of the layer 780a and the layer 790a are replaced with each other, and the above structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer and may further include an electron-blocking layer over the hole-transport layer. The layer 790a includes an electron-transport layer and may further include a hole-blocking layer between the light-emitting layer 771 and the electron-transport layer. The layer 780b includes a hole-transport layer and may further include an electron-blocking layer over the hole-transport layer. The layer 790b includes an electron-transport layer and an electron-injection layer over the electron-transport layer and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer and may further include a hole-blocking layer over the electron-transport layer. The layer 790a includes a hole-transport layer and may further include an electron-blocking layer between the light-emitting layer 771 and the hole-transport layer. The layer 780b includes an electron-transport layer and may further include a hole-blocking layer over the electron-transport layer. The layer 790b includes a hole-transport layer and a hole-injection layer over the hole-transport layer and may further include an electron-blocking layer between the light-emitting layer 772 and the hole-transport layer.

In the case of manufacturing a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

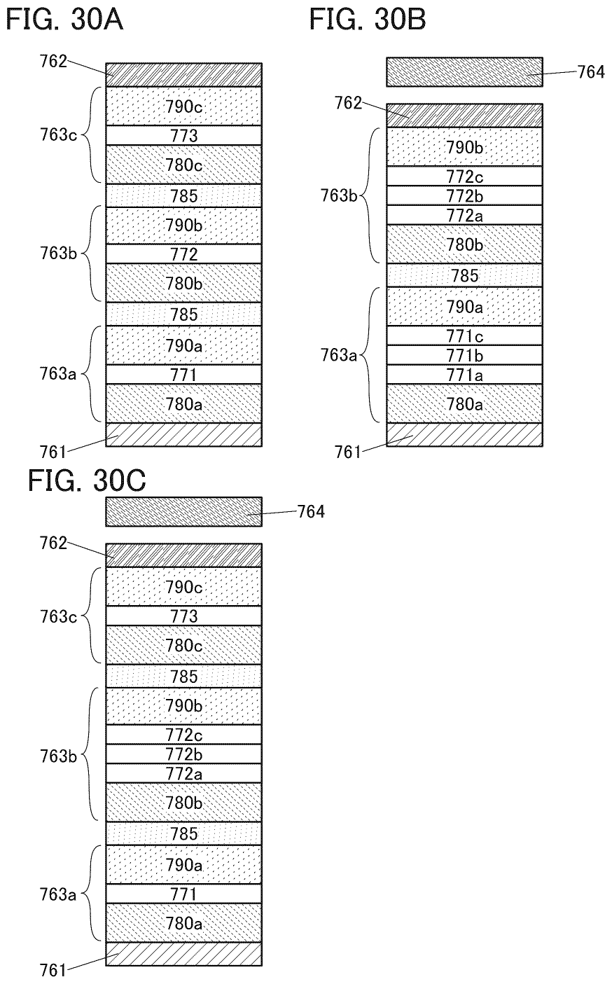

Structures illustrated in FIG. 30A to FIG. 30C can be given as examples of the light-emitting device having a tandem structure.

FIG. 30A illustrates a structure including three light-emitting units. As illustrated in FIG. 30A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 30A, light-emitting substances that emit light of different colors can be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

FIG. 30B illustrates a tandem light-emitting device in which light-emitting units each including a plurality of light-emitting layers are stacked. FIG. 30B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 30B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 30B is a W\W two-unit tandem structure. Note that there is no particular limitation on the stacking order of the light-emitting substances that emit light of complementary colors. The practitioner can select the optimal stacking order as appropriate. Although not illustrated, a W\W\W three-unit tandem structure or a tandem structure with four or more units may be employed. Note that “a\b” means that a light-emitting unit containing a light-emitting substance that emits light of b is provided over a light-emitting unit containing a light-emitting substance that emits light of a with a charge-generation layer therebetween, where a and b represent colors.

Other examples of the structure of a light-emitting device having a tandem structure include: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

As illustrated in FIG. 30C, a light-emitting unit including one light-emitting layer and a light-emitting unit including a plurality of light-emitting layers may be combined.

Specifically, in the structure illustrated in FIG. 30C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes a layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 30C, for example, a B\R·G·YG\B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display apparatus includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used also as the electrode through which light is not extracted. In that case, the electrode is preferably provided between the reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Accordingly, one of the pair of electrodes of the light-emitting device preferably includes an electrode having a transmitting property and a reflecting property with respect to visible light (a semi-transmissive and semi-reflective electrode), and the other is preferably an electrode having a reflecting property with respect to visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer having a visible-light-transmitting property (a transparent electrode).

The light transmittance of the transparent electrode is higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting device includes at least a light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be contained. Each layer included in the light-emitting device can be formed, for example, by an evaporation method (including a vacuum evaporation method), a transfer method, a printing method, an inkjet method, or a coating method.

The light-emitting layer contains one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property that can be used for the hole-transport layer and will be described later. As the electron-transport material, it is possible to use a material with a high electron-transport property that can be used for the electron-transport layer and will be described later. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer that injects holes from an anode to the hole-transport layer and contains a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property that can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable because it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

As the material with a high hole-injection property, a material that contains a hole-transport material and the above-described oxide of a metal belonging to Group 4 to Group 8 of the periodic table (typically, molybdenum oxide) may be used, for example.

The hole-transport layer is a layer transporting holes, which are injected from the anode by the hole-injection layer, to a light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino [2,3-a: 2′,3′-c]phenazine (abbreviation: HATNA), 2,4,6-tris [3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When two light-emitting units are stacked, provision of the charge-generation layer between the light-emitting units can suppress an increase in driving voltage.

This embodiment can be combined with any of the other embodiments as appropriate.

### Embodiment 6

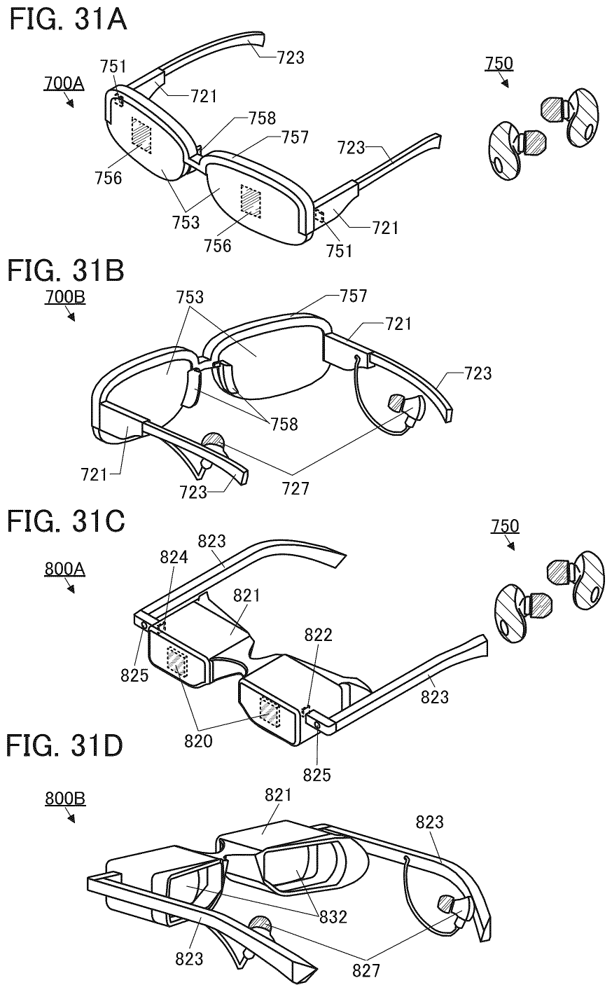

In this embodiment, electronic devices of one embodiment of the present invention will be described with reference to FIG. 31 to FIG. 33.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have high resolution and thus can be suitably used for an electronic device including a relatively small display portion. Examples of such an electronic device include watch-type and bracelet-type information terminals (wearable devices) and wearable devices that can be worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, still further preferably higher than or equal to 500 ppi, still further preferably higher than or equal to 1,000 ppi, still further preferably higher than or equal to 2,000 ppi, still further preferably higher than or equal to 3,000 ppi, still further preferably higher than or equal to 5,000 ppi, yet further preferably higher than or equal to 7,000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, smell, or infrared rays).

The electronic device in this embodiment can have a variety of functions. For example, the electronic device can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices are described with reference to FIG. 31A to FIG. 31D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 31A and an electronic device 700B illustrated in FIG. 31B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device with extremely high resolution can be achieved.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing to be executed. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Various touch sensors can be applied to the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 31C and an electronic device 800B illustrated in FIG. 31D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic device with extremely high resolution can be achieved. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 31C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Note that although an example where the image capturing portion 825 is provided is described here, a range sensor (hereinafter, also referred to as a sensing portion) that is capable of measuring a distance from an object may be provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 31A has a function of transmitting information to the earphones 750 with the wireless communication function. As another example, the electronic device 800A in FIG. 31C has a function of transmitting information to the earphones 750 with the wireless communication function.

The electronic device may include an earphone portion. The electronic device 700B illustrated in FIG. 31B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 31D includes earphone portions 827. For example, the earphone portion 827 can be connected to the control portion 824 by wire. Part of a wiring that connects the earphone portion 827 and the control portion 824 may be positioned inside the housing 821 or the wearing portion 823. The earphone portions 827 and the wearing portions 823 may include magnets. This structure is preferably employed, in which case the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

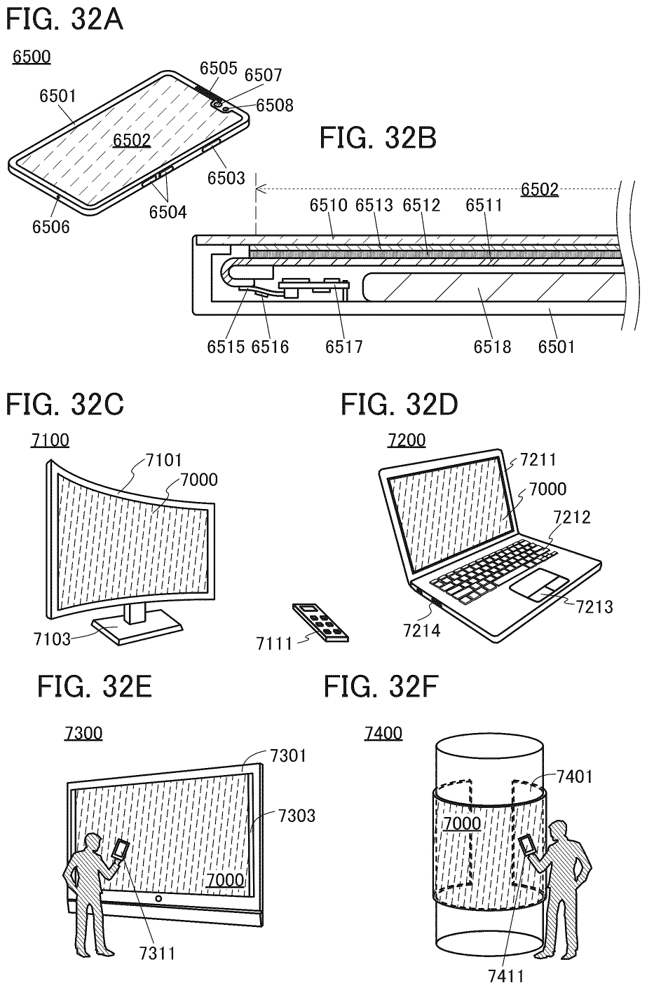

An electronic device 6500 illustrated in FIG. 32A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 32B is a schematic cross-sectional view including an end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus with flexibility of one embodiment of the present invention can be used for the display panel 6511. Thus, an extremely lightweight electronic device can be achieved. Since the display panel 6511 is extremely thin, the battery 6518 with high capacity can be mounted with the thickness of the electronic device controlled. Moreover, part of the display panel 6511 is folded back so that a connection portion with the FPC 6515 is provided on the back side of the display portion 6502, whereby an electronic device with a narrow bezel can be obtained.

FIG. 32C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000.

Operation of the television device 7100 illustrated in FIG. 32C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be operated.

Note that the television device 7100 has a structure in which a receiver, a modem, and the like are provided. A general television broadcast can be received with the receiver. In addition, when the television device is connected to a communication network with or without wires via the modem, one-way (from a sender to a receiver) or two-way (between a sender and a receiver or between receivers) data communication can be performed.

FIG. 32D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000.

FIG. 32E and FIG. 32F illustrate examples of digital signage.

Digital signage 7300 illustrated in FIG. 32E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 32F illustrates digital signage 7400 attached to a cylindrical pillar 7401. The digital signage 7400 includes the display portion 7000 provided along a curved surface of the pillar 7401.

The display apparatus of one embodiment of the present invention can be used in the display portion 7000 in each of FIG. 32E and FIG. 32F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 32E and FIG. 32F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

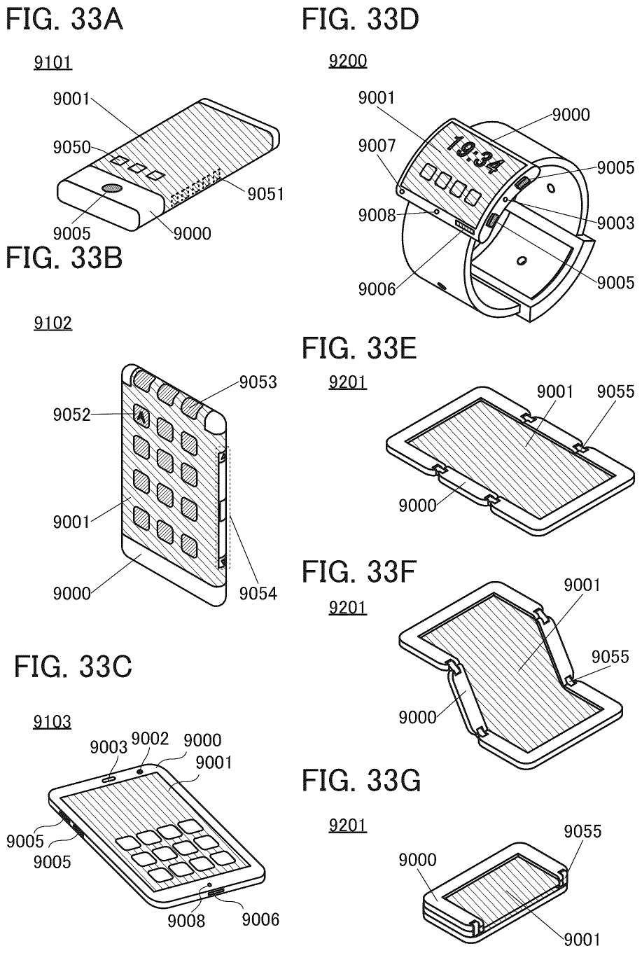

Electronic devices illustrated in FIG. 33A to FIG. 33G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, smell, or infrared rays), a microphone 9008, and the like.

In FIG. 33A to FIG. 33G, the display apparatus of one embodiment of the present invention can be used in the display portion 9001.

The electronic devices illustrated in FIG. 33A to FIG. 33G have a variety of functions. For example, the electronic devices can have a function of displaying a variety of data (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each include a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 33A to FIG. 33G will be described in detail below.

FIG. 33A is a perspective view showing a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display letters and image information on its plurality of surfaces. FIG. 33A illustrates an example in which three icons 9050 are displayed. Information 9051 indicated by dashed rectangles can be displayed on another surface of the display portion 9001. Examples of the information 9051 include notification of reception of an e-mail, an SNS, or an incoming call, the title and sender of an e-mail, an SNS, or the like, the date, the time, remaining battery, and the radio field intensity. Alternatively, the icon 9050 or the like may be displayed in the position where the information 9051 is displayed.

FIG. 33B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 33C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, the camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 33D is a perspective view illustrating a watch-type portable information terminal 9200. The portable information terminal 9200 can be used as a smartwatch (registered trademark), for example. The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 33E to FIG. 33G are perspective views illustrating a foldable portable information terminal 9201. FIG. 33E is a perspective view of an opened state of the portable information terminal 9201, FIG. 33G is a perspective view of a folded state thereof, and FIG. 33F is a perspective view of a state in the middle of change from one of FIG. 33E and FIG. 33G to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature greater than or equal to 0.1 mm and less than or equal to 150 mm.

This embodiment can be combined with any of the other embodiments as appropriate.

### REFERENCE NUMERALS

11B: subpixel, 11G: subpixel, 11R: subpixel, 100A: display apparatus, 100B: display apparatus, 100C: display apparatus, 100D: display apparatus, 100E: display apparatus, 100F: display apparatus, 100G: display apparatus, 100H: display apparatus, 100: display apparatus, 101: layer, 103: region, 110a: subpixel, 110b: subpixel, 110c: subpixel, 110d: subpixel, 110: pixel, 111B: pixel electrode, 111G: pixel electrode, 111R: pixel electrode, 112B: conductive layer, 112G: conductive layer, 112R: conductive layer, 113b: material layer, 113s: material layer, 113t: region, 113B: EL layer, 113: EL layer, 114A: insulating film, 114: sidewall insulating layer, 115: common electrode, 116B: optical adjustment layer, 116G: optical adjustment layer, 116R: optical adjustment layer, 117: light-blocking layer, 120: substrate, 122: resin layer, 123: conductive layer, 124a: pixel, 124b: pixel, 125A: insulating film, 125B: insulating layer, 125: insulating layer, 126B: conductive layer, 126G: conductive layer, 126R: conductive layer, 127a: insulating film, 127b: insulating layer, 127: insulating layer, 128: layer, 129B: conductive layer, 129G: conductive layer, 129R: conductive layer, 130B: light-emitting device, 130G: light-emitting device, 130R: light-emitting device, 131: protective layer, 132B: coloring layer, 132G: coloring layer, 132R: coloring layer, 133: lens, 134: insulating layer, 135: insulating layer, 136: mask, 137B: light-emitting device, 137G: light-emitting device, 137R: light-emitting device, 139: light, 140: connection portion, 142: adhesive layer, 150A: region, 150B: region, 150C: region, 150D: region, 150E: region, 150F: region, 151: substrate, 152: substrate, 153: insulating layer, 154B: subpixel, 154G: subpixel, 154R: subpixel, 155B: subpixel, 155G: subpixel, 155R: subpixel, 162: display portion, 164: circuit, 165: wiring, 166: conductive layer, 171: light-blocking layer, 172: FPC, 173: IC, 175G: color conversion layer, 175R: color conversion layer, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: wearing portion, 727: earphone portion, 750: earphone, 751: display panel, 753: optical member, 756: display region, 757: frame, 758: node pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device;
a second light-emitting device;
a first sidewall insulating layer;
a second sidewall insulating layer;
a first insulating layer;
a first coloring layer; and
a second coloring layer,
wherein the first light-emitting device comprises a first pixel electrode, a first EL layer over the first pixel electrode, and a common electrode over the first EL layer,
wherein the second light-emitting device comprises a second pixel electrode, a second EL layer over the second pixel electrode, and the common electrode over the second EL layer,
wherein the first EL layer and the second EL layer each comprise a first light-emitting material and a second light-emitting material,
wherein the first light-emitting material is configured to emit blue light,
wherein the second light-emitting material is configured to emit light having a longer wavelength than blue light,
wherein the first sidewall insulating layer is in contact with a side surface of the first pixel electrode,
wherein the second sidewall insulating layer is in contact with a side surface of the second pixel electrode,
wherein the first insulating layer covers a side surface and part of a top surface of the first EL layer and a side surface and part of a top surface of the second EL layer,
wherein the first coloring layer overlaps with the first light-emitting device,
wherein the second coloring layer overlaps with the second light-emitting device, and
wherein the first coloring layer and the second coloring layer have functions of transmitting are configured to transmit light of different colors.

2. The display apparatus according to claim 1, further comprising:
a material layer between the first light-emitting device and the second light-emitting device,
wherein the material layer comprises the first light-emitting material and the second light-emitting material.

3. The display apparatus according to claim 1,
wherein the first sidewall insulating layer and the second sidewall insulating layer each comprise an inorganic insulating material.

4. The display apparatus according to claim 1,
wherein the first insulating layer has a tapered end portion.

5. The display apparatus according to claim 1,
wherein the first insulating layer comprises an organic insulating material.

6. The display apparatus according to claim 1, further comprising:
a second insulating layer covering the side surface and the part of the top surface of the first EL layer and the side surface and the part of the top surface of the second EL layer,
wherein the first insulating layer is provided over the second insulating layer.

7. The display apparatus according to claim 6,
wherein the second insulating layer has a tapered end portion.

8. The display apparatus according to claim 6,
wherein the second insulating layer comprises an inorganic insulating material.

9. (canceled)

10. (canceled)
